(19) United States
(12) Patent Application Publication
(10) Pub. No.: US 2024/0315083 A1
(43) Pub. Date: Sep. 19, 2024

(54) DISPLAY DEVICE AND METHOD OF FABRICATING THE SAME

(71) Applicant: Samsung Display Co., LTD., Yongin-si (KR)

(72) Inventor: Jin Ho JU, Yongin-si (KR)

(21) Appl. No.: 18/414,105

(22) Filed: Jan. 16, 2024

(30) Foreign Application Priority Data
Mar. 14, 2023 (KR) 10-2023-0033405

(51) Int. Cl. H10K 59/122; H10K 59/12; H10K 59/80

(52) U.S. Cl. CPC H10K 59/122; H10K 59/1201; H10K 59/873; H10K 59/879

(57) ABSTRACT

A display device includes first and second anodes on a substrate, a bank structure provided with first and second openings overlapping the first and second anodes, first and second light-emitting layers on the first and second anodes, first and second cathodes on the first and second light-emitting layers, a first encapsulation layer including first and second inorganic layers on the first and second cathodes, first and second optical patterns on the first and second inorganic layers in the first and second openings, a second encapsulation layer on the first encapsulation layer and the first and second optical patterns. The bank structure includes first and second bank layers including different materials, and the second bank layer includes a tip protruding beyond the first bank layer on sidewalls defining the first and second openings, and the first and second optical patterns have a different refractive index from the second encapsulation layer.

This application claims priority to Korean Patent Application No. 10-2023-0033405, filed on Mar. 14, 2023, and all the benefits accruing therefrom under 35 U.S.C. § 119, the content of which in its entirety is herein incorporated by reference.

### BACKGROUND

### 1. Field

The disclosure relates to a display device and a method of fabricating the display device.

### 2. Description of the Related Art

As the information society has developed, the demand for display devices for displaying images has diversified. For example, display devices have been applied to various electronic devices such as smart phones, digital cameras, notebook computers, navigation systems, and smart televisions. Here, the display devices may be flat panel display devices such as a liquid crystal display (LCD) device, a field emission display (FED) device, or an organic light-emitting diode (OLED) display device. Flat-panel light-emitting display devices, in particular, include light-emitting elements capable of allowing pixels to emit light, and can thus display images without using backlight units for providing light to display panels.

### SUMMARY

Embodiments of the disclosure provide a display device in which light-emitting elements are formed to be separate between emission areas, without using mask processes, and the efficiency of emitting light can be improved via organic films disposed in the emission areas.

However, embodiments of the disclosure are not restricted to those set forth herein. The above and other features of embodiments of the disclosure will become more apparent to one of ordinary skill in the art to which the disclosure pertains by referencing the detailed description of the disclosure given below.

According to an embodiment of the disclosure, a display device includes first and second anodes disposed on a substrate to be spaced apart from each other, an inorganic insulating layer disposed on the substrate and in part on the first and second anodes, a bank structure disposed on the inorganic insulating layer, wherein a first opening and a second opening, which overlap the first and second anodes, respectively, are defined through the bank structure, a first light-emitting layer disposed on the first anode, a second light-emitting layer disposed on the second anode, a first cathode disposed on the first light-emitting layer, a second cathode disposed on the second light-emitting layer, a first encapsulation layer including a first inorganic layer, which is disposed on the first cathode, and a second inorganic layer, which is disposed on the second cathode, a first optical pattern disposed on the first inorganic layer and in part in the first opening, where the first optical pattern overlaps the first light-emitting layer, a second optical pattern disposed on the first inorganic layer and in the second opening, where the second optical pattern overlaps the second light-emitting layer, a second encapsulation layer disposed on the first encapsulation layer, the first optical pattern, and the second optical pattern, a third encapsulation layer disposed on the second encapsulation layer. In such an embodiment, the bank structure includes a first bank layer and a second bank layer, which is disposed on the first bank layer, includes a different material from the first bank layer, and includes a tip protruding beyond the first bank layer from sidewalls of the bank structure defining each of the first and second openings, and the first and second optical patterns have a different refractive index from the second encapsulation layer.

In an embodiment, the first bank layer may include aluminum (Al), and the second bank layer may include titanium (Ti).

In an embodiment, the first and second cathodes may be in direct contact with side surfaces of the first bank layer.

In an embodiment, the display device may further include a first organic pattern disposed on the second bank layer to surround the first opening, where the first organic pattern may include a same material as the first light-emitting layer, a first electrode pattern disposed on the first organic pattern, the first electrode pattern including the same material as the first cathode, a second organic pattern disposed on the second bank layer to surround the second opening, where the second organic pattern include a same material as the second light-emitting layer, and a second electrode pattern disposed on the second organic pattern, where the second electrode pattern include a same material as the second cathode, wherein the first inorganic layer may be disposed on the first electrode pattern, and the second inorganic layer may be disposed on the second electrode pattern.

In an embodiment, the first inorganic layer may be disposed on the sidewalls of the bank structure defining the first opening, and the second inorganic layer may be disposed on the sidewalls of the bank structure defining the second opening.

In an embodiment, outer surfaces of the first and second optical patterns may have a curved shape, ends of an outer surface of the first optical pattern may be aligned with the first inorganic layer, and ends of an outer surface of the second optical pattern may be aligned with the second inorganic layer.

In an embodiment, the first and second optical patterns may have a greater refractive index than the second encapsulation layer, and the ends of the outer surface of each of the first and second optical patterns may form an acute angle with a top surface of the first or second inorganic layer.

In an embodiment, the first and second optical patterns may have a refractive index of about 1.6 or greater, and the second encapsulation layer may have a refractive index less than about 1.6.

In an embodiment, a minimum distance between the first and second optical patterns may be the same as a distance between the first and second inorganic layers.

In an embodiment, the first and second optical patterns may have a less refractive index than the second encapsulation layer, and the ends of the outer surface of each of the first and second optical patterns may form an obtuse angle with the top surface of the first or second inorganic layer.

In an embodiment, the first and second optical patterns may have a refractive index less than about 1.6, and the second encapsulation layer may have a refractive index of about 1.6 or greater.

In an embodiment, a minimum distance between the first and second optical patterns may be less than a distance between the first and second inorganic layers.

In an embodiment, the inorganic insulating layer may be not in contact with top surfaces of the first and second anodes, the first light-emitting layer may be disposed in part between the first anode and the inorganic insulating layer, and the second light-emitting layer may be disposed in part between the second anode and the inorganic insulating layer.

In an embodiment, the display device may further include residual patterns disposed between the inorganic insulating layer and the first and second anodes.

In an embodiment, the display device may further include a touch layer disposed on the third encapsulation layer, a light-blocking layer provided with a first opening hole, which overlaps the first opening, and a second opening hole, which overlaps the second opening, and first and second color filters disposed on the light-blocking layer, where the first and second color filters may overlap the first and second opening holes, respectively.

According to an embodiment of the disclosure, a method of fabricating a display device, includes forming a plurality of anodes, which are spaced apart from one another on a substrate, a sacrificial layer, which is disposed on the anodes, and first and second bank material layers, which are disposed on the sacrificial layer, on the substrate, forming a first hole, which overlaps one of the anodes and exposes part of the sacrificial layer on a corresponding anode through the first and second bank material layers, forming a tip, which is a part of the second bank material layer protruding beyond sides of the first bank material layer, by etching the sacrificial layer and sidewalls defining the first hole, forming a first light-emitting layer and a first cathode on the anode in a first opening, which is formed by etching the first hole, and forming a first inorganic layer on the first cathode and the second bank material layer, forming a first optical pattern on the first inorganic layer, in the first opening, etching the first inorganic layer in a way such that the first inorganic layer on the second bank material layer, except for a part thereof overlapping the first optical pattern, is removed, and forming an organic encapsulation layer on the first optical pattern, where the organic encapsulation layer has a different refractive index from the first optical pattern.

In an embodiment, the method may further include after the etching the first inorganic layer and before the forming the organic encapsulation layer: forming a second hole through the first and second bank material layers to overlap a corresponding one of the anodes, forming a second opening by etching sidewalls defining the second hole, forming a second light-emitting layer and a second cathode on the corresponding one of the anodes in the second opening, forming a second inorganic layer on the second cathode and the second bank material layer, forming a second optical pattern on the second inorganic layer, in the second opening, and etching the second inorganic layer in a way such that the second inorganic layer on the second bank material layer, except for a part thereof overlapping the second optical pattern, is removed.

In an embodiment, the first and second optical patterns may have a greater refractive index than the organic encapsulation layer, outer surfaces of the first and second optical patterns may have a curved shape, and ends of the outer surface of each of the first and second optical patterns may form an acute angle with a top surface of the first or second inorganic layer.

In an embodiment, the ends of the outer surface of the first optical pattern may be aligned with the first inorganic layer, and the ends of the outer surface of the second optical pattern may be aligned with the second inorganic layer.

In an embodiment, the first bank material layer may include aluminum (Al), and the second bank material layer may include titanium (Ti).

According to embodiments of the disclosure, as optical patterns having a different refractive index from an organic encapsulation layer are provided in openings of a bank structure, the emission efficiency of a display device can be improved.

It should be noted that the effects of the disclosure are not limited to those described above, and other effects of the disclosure will be apparent from the following description.

### BRIEF DESCRIPTION OF THE DRAWINGS

The above and other features of embodiments of the disclosure will become more apparent by describing in detail embodiments thereof with reference to the accompanying drawings, in which:

FIG. 1 is a perspective view of an electronic device according to an embodiment of the disclosure;

FIG. 2 is a perspective view of a display device included in the electronic device of FIG. 1;

FIG. 3A is a cross-sectional view of the display device of FIG. 2, as viewed from a side of the display device of FIG. 2;

FIG. 3B is a cross-sectional view of the display device of FIG. 2, as viewed from another side of the display device of FIG. 2;

FIG. 4 is a plan view illustrating a display layer of the display device of FIG. 2;

FIG. 5 is a plan view illustrating the layout of emission areas and color filters in a display area of the display device of FIG. 2;

FIG. 6 is a cross-sectional view illustrating part of the display device of FIG. 2;

FIG. 7 is an enlarged cross-sectional view illustrating a first emission area of FIG. 6;

FIGS. 8 through 16 are cross-sectional views illustrating a display area of a display device for explaining a method of fabricating a display device according to an embodiment of the disclosure;

FIG. 17 is a cross-sectional view illustrating part of a display device according to an alternative embodiment of the disclosure; and

FIG. 18 is an enlarged cross-sectional view illustrating a first emission area of FIG. 17.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

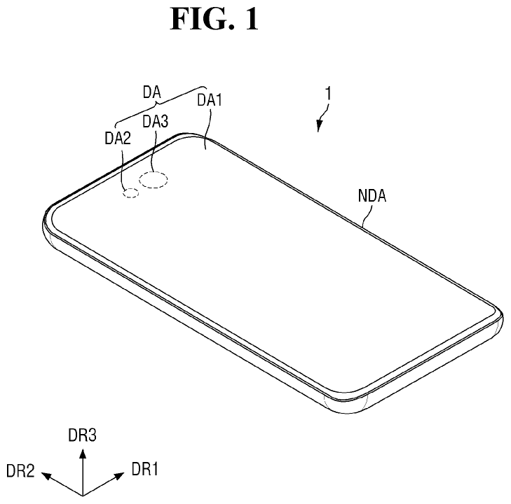

FIG. 1 is a perspective view of an electronic device according to an embodiment of the disclosure.

Referring to FIG. 1, an embodiment of an electronic device 1 displays a moving image or a still image. The electronic device 1 may refer to nearly all types of electronic devices including a display screen, for example, a television (TV), a notebook computer, a monitor, an electronic billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book reader, a portable multimedia player (PMP), a navigation device, a gaming console, a digital camera, and a camcorder.

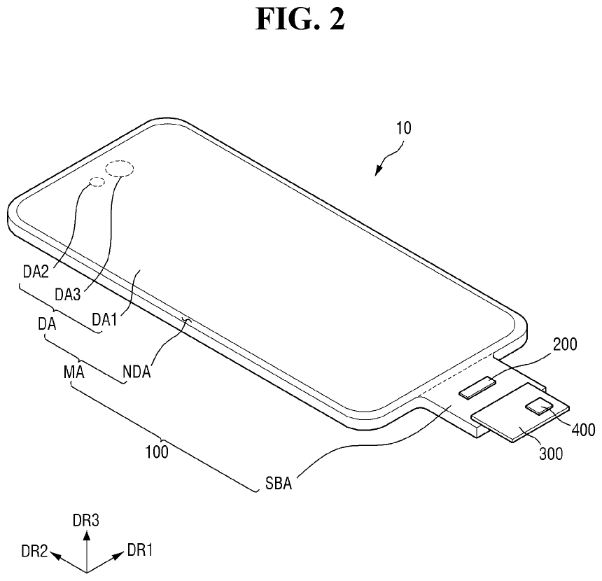

The electronic device 1 may include a display device 10 of FIG. 2. In an embodiment, the display device 10 may be an inorganic light-emitting diode display device, an organic light-emitting diode (OLED) display device, a quantum-dot light-emitting display device, a plasma display device, or a field emission display (FED) device. Hereinafter, for convenience of description, embodiment where the display device 10 is an OLED display device will be described in detail, but the disclosure is not limited thereto. The display device 10 may also be applicable to various other display devices.

The shape of the electronic device 1 may be variously modified. In an embodiment, for example, the electronic device 1 may have a rectangular shape that extends longer horizontally than vertically, a rectangular shape that extends longer vertically than horizontally, a square shape, a rectangular shape with rounded corners, another polygonal shape, or a circular shape. A display area DA of the electronic device 1 may generally have a similar shape to an overall shape of the electronic device 1. FIG. 1 illustrates an embodiment where the electronic device 1 has a rectangular shape that extends longer in a second direction DR2 than in a first direction DR1.

In an embodiment, the electronic device 1 may include a display area DA and a non-display area NDA. The display area DA may be an area where an image can be displayed, and the non-display area NDA may be an area where an image is not displayed. The display area DA may also be referred to as an active area, and the non-display area NDA may also be referred to as an inactive area. The display area DA may generally account for the middle of the electronic device 1.

The display area DA may include first, second, and third display areas DA1, DA2, and DA3. The second and third display areas DA2 and DA3 may be component areas where components for adding various functions are disposed.

FIG. 2 is a perspective view of a display device included in the electronic device of FIG. 1.

Referring to FIG. 2, an embodiment of the electronic device 1 of FIG. 1 may include the display device 10. The display device 10 may provide a display screen for the electronic device 1. The display device 10 may have a similar shape to the overall shape of the electronic device 1. In an embodiment, for example, the display device 10 may have an almost rectangular shape having short sides extending in the first direction DR1 and long sides extending in the second direction DR1. The corners where the short sides and the long sides of the display device 10 meet each other may be rounded to have a predetermined curvature or may be right-angled. The shape of the display device 10 is not particularly limited, and the display device 10 may be formed in various other shapes such as another polygonal shape, a circular shape, or an elliptical shape.

The display device 10 may include a display panel 100, a display driving unit 200, a circuit board 300, and a touch driving unit 400. Here, a driving unit may be a driver or a driving circuit, that is, the display driving unit 200 may be a display driver and the touch driving unit 400 may be a touch driver.

The display panel 100 may include a main area MA and a subarea SBA.

The main area MA may include a display area DA, which includes pixels for displaying an image, and a non-display area NDA, which is disposed around the display area DA. The display area DA may include the first, second, and third display areas DA1, DA2, and DA3. The display area DA may emit light through a plurality of emission areas or openings. In an embodiment, for example, the display panel 100 may include pixel circuits including switching elements, a pixel-defining film defining the emission areas or the openings, and self-light-emitting elements.

In an embodiment, for example, the self-light-emitting elements may include organic light-emitting diodes (OLEDs), quantum-dot light-emitting diodes (LEDs) including a quantum-dot light-emitting layer, inorganic LEDs including an inorganic semiconductor, and/or micro LEDs, but the disclosure is not limited thereto.

The non-display area NDA may surround the outside of the display area DA. The non-display area NDA may be defined as an edge part of the main area MA. The non-display area NDA may include a gate driving unit (not illustrated) for providing gate signals to gate lines and fan-out lines (not illustrated) connecting the display driving unit 200 and the display area DA to each other.

The subarea SBA may be an area extending from one side of the main area MA. The subarea SBA may include a flexible material that is bendable, foldable, or rollable. In an embodiment, for example, where the subarea SBA is bendable, the subarea SBA may be bent to overlap the main area MA in a thickness direction (or a third direction DR3). The subarea SBA may include the display driving unit 200 and a pad unit, which is connected to the circuit board 300. Alternatively, the subarea SBA may not be provided, and the display driving unit 200 and the pad unit may be disposed in the non-display area NDA.

The display driving unit 200 may output signals and voltages for driving the display panel 100. The display driving unit 200 may provide data voltages to data lines. The display driving unit 200 may provide power supply voltages to power lines and may provide gate control signals to the gate driving unit. The display driving unit 200 may be formed as an integrated circuit (IC) and may be mounted on the display panel 100 in a chip-on-glass (COG) or chip-on-plastic (COP) manner or via ultrasonic bonding. In an embodiment, for example, the display driving unit 200 may be disposed in the subarea SBA and may overlap the main area MA in the thickness direction when the subarea SBA is bent. In an alternative embodiment, for example, the display driving unit 200 may be mounted on the circuit board 300.

The circuit board 300 may be attached to the pad unit of the display panel 100 via an anisotropic conductive film (ACF). Lead lines of the circuit board 300 may be electrically connected to the pad unit of the display panel 100. The circuit board 300 may be a printed circuit board (PCB), a flexible PCB (FPCB), or a flexible film such as a chip-on-film (COF).

The touch driving unit 400 may be mounted on the circuit board 300. The touch driving unit 400 may be electrically connected to a touch sensing unit of the display panel 100. The touch driving unit 400 may provide a touch driving signal to a plurality of touch electrodes of the touch sensing unit and may sense capacitance variations between the touch electrodes. In an embodiment, for example, the touch driving signal may be a pulse signal having a predetermined frequency. The touch driving unit 400 may calculate the presence and coordinates of input based on the capacitance variations between the touch electrodes. The touch driving unit 400 may be formed as an integrated circuit (IC).

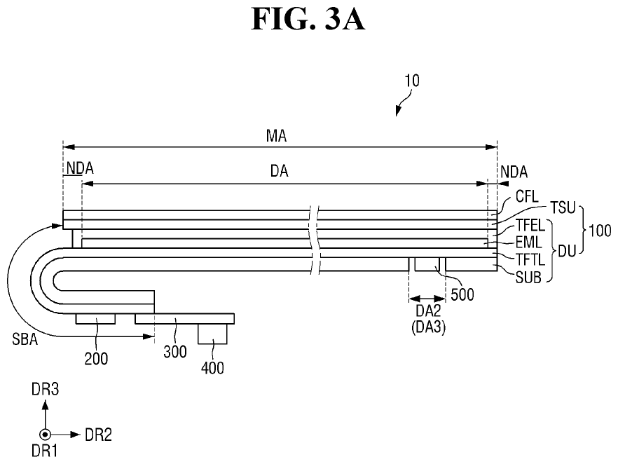

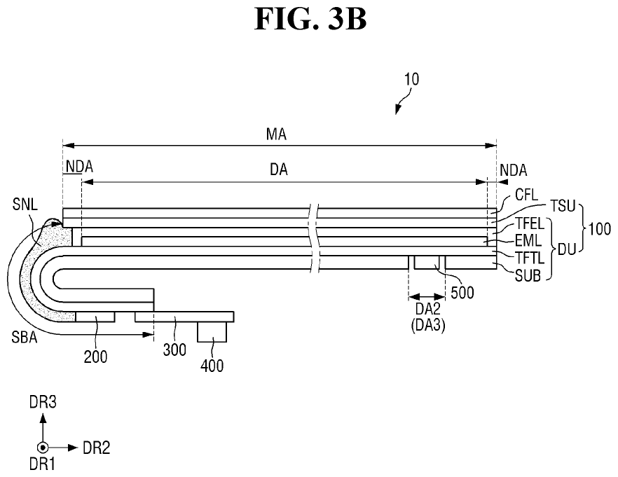

FIG. 3A is a cross-sectional view of the display device of FIG. 2, as viewed from a side of the display device of FIG. 2.

Referring to FIG. 3A, the display panel 100 may include a display layer DU, a touch sensing layer TSU, and a color filter layer CFL. The display layer DU may include a substrate SUB, a thin-film transistor (TFT) layer TFTL, a light-emitting element layer EML, and a thin-film encapsulation layer TFEL.

The substrate SUB may be a base substrate or a base member. The substrate SUB may be a flexible substrate that is bendable, foldable, or rollable. In an embodiment, for example, the substrate SUB may include a polymer resin such as polyimide (PI), but the disclosure is not limited thereto. In an alternative embodiment, for example, the substrate SUB may include a glass material or a metal material.

The TFT layer TFTL may be disposed on the substrate SUB. The TFT layer TFTL may include a plurality of TFTs that form the pixel circuitry of pixels. The TFT layer TFTL may further include gate lines, data lines, power lines, gate control lines, and fan-out lines connecting the display driving unit 200 and the data lines, and lead lines connecting the display driving unit 200 and the pad unit. The TFTs may include semiconductor regions, source electrodes, drain electrodes, and gate electrodes. In an embodiment, for example, where the gate driving unit is formed on one side of the non-display area NDA of the display panel 100, the gate driving unit may include TFTs.

The TFT layer TFTL may be disposed in the display area DA, the non-display area NDA, and the subarea SBA. The TFTs, the gate lines, the data lines, and the power lines of the TFT layer TFTL may be disposed in the display area DA. The gate control lines and the fan-out lines of the TFT layer TFTL may be disposed in the non-display area NDA. The lead lines of the TFT layer TFTL may be disposed in the subarea SBA.

The light-emitting element layer EML may be disposed on the TFT layer TFTL. The light-emitting element layer EML may include a plurality of light-emitting elements, which include first electrodes, second electrodes, light-emitting layers and emit light, and a bank structure, which defines the pixels. The light-emitting elements of the light-emitting element layer EML may be disposed in the display area DA.

The light-emitting layers may be organic light-emitting layers including an organic material. The light-emitting layers may include hole transport layers, organic light-emitting layers, and electron transport layers. As the first electrodes receive a voltage through the TFTs of the TFT layer TFTL and the second electrodes receive a cathode voltage, holes and electrons may move to the organic emission layers through the hole transport layers and the electron transport layers, respectively, and may combine together in the organic light-emitting layers to emit light.

Alternatively, the light-emitting elements may be quantum-dot LEDs including quantum-dot light-emitting layers, inorganic LEDs including an inorganic semiconductor, or micro-LEDs.

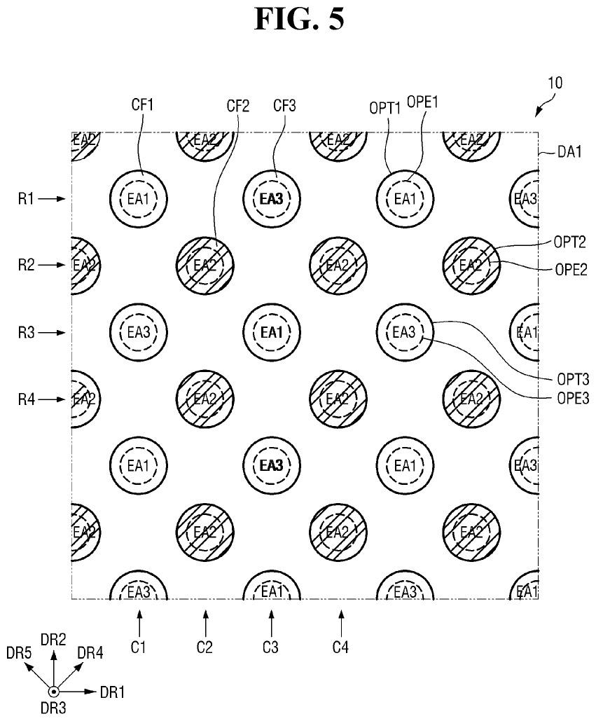

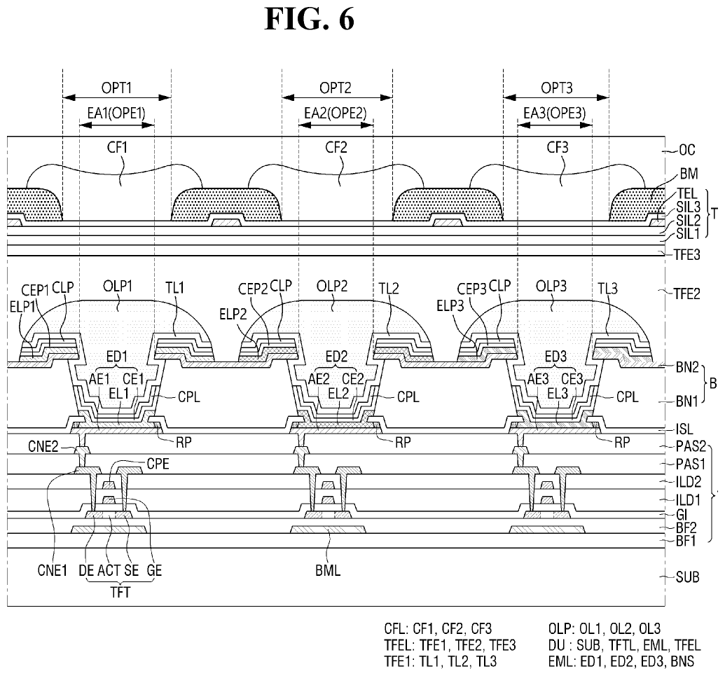

The display device 10 may include a plurality of color filters (“CF1,” “CF2,” and “CF3” of FIGS. 5 and 6), which are disposed on the light-emitting elements of the light-emitting element layer EML. Each of the color filters (CF1, CF2, and CF3) may selectively transmit light of a particular wavelength therethrough and may block or absorb light of other wavelengths. The color filters (CF1, CF2, and CF3) may reduce reflected light of external light by absorbing some of the external light. Accordingly, the color filters (CF1, CF2, and CF3) can prevent color distortion that may be caused by the external light. As the color filters (CF1, CF2, and CF3) are disposed on the light-emitting elements, the display device 10 may not include a separate substrate for the color filters (CF1, CF2, and CF3). Therefore, the thickness of the display device 10 can be reduced.

The thin-film encapsulation layer TFEL may cover the top surface and sides of the light-emitting element layer EML and may protect the light-emitting element layer EML. The thin-film encapsulation layer TFEL may include at least one inorganic film and at least one organic film for encapsulating the light-emitting element layer EML.

The touch sensing layer TSU may be disposed on the thin-film encapsulation layer TFEL. The touch sensing layer TSU may include a plurality of touch electrodes for detecting touch input from a user in a capacitive manner and touch lines for connecting the touch electrodes and the touch driving unit 400. In an embodiment, for example, the touch sensing layer TSU may sense touch input from the user in a mutual capacitance manner or in a self-capacitance manner.

Alternatively, the touch sensing layer TSU may be disposed on a separate substrate, which is disposed on the display layer DU. In such an embodiment, the separate substrate may be a base member encapsulating the display layer DU.

The touch electrodes of the touch sensing layer TSU may be disposed in a touch sensor area overlapping with the display area DA. The touch lines of the touch sensing layer TSU may be disposed in a touch peripheral area overlapping the non-display area NDA.

In some embodiments, the display device 10 may further include an optical device 500. The optical device 500 may be disposed in the second or third display area DA2 or DA3. The optical device 500 may emit or receive infrared light, ultraviolet light, or visible light. In an embodiment, for example, the optical device 500 may be an optical sensor capable of sensing light incident upon the display device 10, such as a proximity sensor, a light sensor, a camera sensor, or an image sensor.

The color filter layer CFL may be disposed on the touch sensing layer TSU. The color filter layer CFL may include the color filters (CF1, CF2, and CF3), which correspond to their respective emission areas. The color filters (CF1, CF2, and CF3) may selectively transmit light of a particular wavelength therethrough and may block or absorb light of other wavelengths. The color filters (CF1, CF2, and CF3) may reduce reflected light of external light by absorbing some of the external light. Accordingly, the color filters (CF1, CF2, and CF3) can prevent color distortion that may be caused by the external light.

As the color filer layer CFL is disposed directly on the thin-film encapsulation layer TFEL, the display device 10 may not include a separate substrate for the color filter layer CFL. Thus, the thickness of the display device 10 can be reduced.

FIG. 3B is a cross-sectional view of the display device of FIG. 2, as viewed from another side of the display device of FIG. 2.

Referring to FIG. 3B, in an embodiment, the display device 10 may further include a substrate protection layer SNL, which is disposed in the subarea SBA of the substrate SUB. The substrate protection layer SNL may be disposed in the subarea SBA, which is bent, and may protect the substrate SUB from external shock. The substrate protection layer SNL may cover side surfaces of the light-emitting element layer EML, the thin-film encapsulation layer TFEL, the touch sensing layer TSU, and the color filter layer CFL, from the bottom surface of the substrate SUB. Although not specifically illustrated, in an embodiment in a state where a cover window is disposed on the display panel 100 of the display device 10, the substrate protection layer SNL may be disposed to fill the gap from the substrate SUB to the bottom of the cover window.

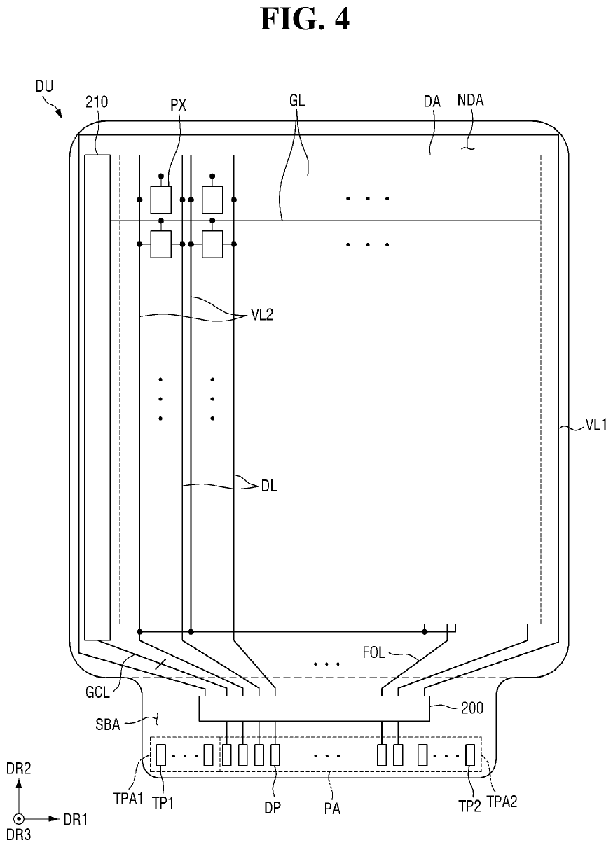

FIG. 4 is a plan view illustrating the display layer of the display device of FIG. 2.

Referring to FIG. 4, in an embodiment, the display layer DU may include the display area DA and the non-display area NDA.

The display area DA may be disposed in the middle of the display panel 100. A plurality of pixels PX, a plurality of gate lines GL, a plurality of data lines DL, and some of a plurality of power lines (e.g., second power lines VL2) may be disposed in the display area DA. The pixels PX may be defined as minimal (or basic) units for emitting light.

The gate lines GL may provide gate signals received from the gate driving unit 210 to the pixels PX. The gate lines GL may extend in the first direction DR1 and may be spaced apart from one another in the second direction DR2, which intersects the first direction DR1.

The data lines DL may provide data voltages received from the display driving unit 200 to the pixels PX. The data lines DL may extend in the second direction DR2 and may be spaced apart from one another in the first direction DR1.

The second power lines VL2 may provide the power supply voltages received from the display driving unit 200 to the pixels PX. Here, the power supply voltages include at least one of a driving voltage, an initialization voltage, and a reference voltage. The second power lines VL2 may extend in the second direction DR2 and may be spaced apart from one another in the first direction DR1.

The non-display area NDA may surround the display area DA. Some of the power lines (e.g., first power lines VL1), the gate driving unit 210, fan-out lines FOL, and gate control lines CGL may be disposed in the non-display area NDA. The gate driving unit 210 may generate a plurality of gate signals based on the gate control signals and may sequentially provide the gate signals to the gate lines GL in a predefined order.

The fan-out lines FOL may extend from the display driving unit 200 to the display area DA. The fan-out lines FOL may provide data voltages received from the display driving unit 200 to the data lines DL.

The gate control lines CGL may extend from the display driving unit 200 to the gate driving unit 210. The gate control lines GCL may provide gate control signals received from the display driving unit 200 to the gate driving unit 210. The gate driving unit 210 is illustrated as being disposed in part of the non-display area NDA on the left side of the display area DA, but the disclosure is not limited thereto. Alternatively, in some embodiments, the display device 10 a plurality of gate driving units 210, which are disposed on the left and right sides of the display area DA.

The first power lines VL1 may be disposed in the non-display area NDA, surrounding the display area DA. The first power lines VL1 may provide power supply voltages, received from the display driving unit 200, to the pixels PX. Here, the power supply voltages may be a low-potential power supply voltages.

The subarea SBA may include the display driving unit 200, a pad area PA, and first and second touch areas TPA1 and TPA2.

The display driving unit 200 may output signals and voltages for driving the display panel 100 to the fan-out lines FOL. The display driving unit 200 may provide data voltages to the data lines DL through the fan-out lines FOL. The data voltages may be provided to the pixels PX and may control the luminance of the pixels PX. The display driving unit 200 may provide gate control signals to the gate driving unit 210 through the gate control lines GCL.

The pad area PA, the first touch pad area TPA1, and the second touch pad area TPA2 may be disposed on an edge of the subarea SBA. The pad area PA, the first touch pad area TPA1, and the second touch pad area TPA2 may be electrically connected to the circuit board 300 via an anisotropic conductive film (ACF) or a self-assembly anisotropic conductive paste (SAP).

The pad area PA may include a plurality of display pads DP. The display pads DP may be connected to a graphics system via the circuit board 300. The display pads DP may be connected to the circuit board 300 and may thus receive digital video data and provide the digital video data to the display driving unit 200. The first touch pad area TPA1 may include a plurality of first touch pads TP1, and the second touch pad area TPA2 may include a plurality of second touch pads TP2.

FIG. 5 is a plan view illustrating the layout of emission areas and color filters in the display area of the display device of FIG. 2.

Referring to FIG. 5, an embodiment of the display device 10 may include a plurality of emission areas (EA1, EA2, and EA3), which are disposed in the display area DA. The display area DA of FIG. 5 is the first display area DA1, and the emission areas (EA1, EA2, and EA3) may be disposed in the first display area DA1. The emission areas (EA1, EA2, and EA3) may also be disposed in the second and third display areas DA2 and DA2.

The emission areas (EA1, EA2, and EA3) may include first emission areas EA1, second emission areas EA2, and third emission areas EA3, which emit light of different colors. The first emission areas EA1, the second emission areas EA2, and the third emission areas EA3 may emit red light, green light, and blue light, respectively, and the colors of beams of light emitted from the emission areas (EA1, EA2, and EA3) may vary depending on the types of light-emitting elements (“ED1”, “ED2”, and “ED3” of FIG. 6) disposed in the light-emitting element layer EML. In an embodiment, for example, the first emission areas EA1 may emit first light, which is red light, the second emission areas EA2 may emit second light, which is green light, and the third emission areas EA3 may emit third light, which is blue light. However, the disclosure is not limited thereto.

The emission areas (EA1, EA2, and EA3) may be arranged in a PenTile™ fashion, for example, in a diamond PenTile™ fashion. In an embodiment, for example, the first emission areas EA1 and the third emission areas EA3 may be spaced apart from one another in the first direction DR1 and may be alternately arranged in the first and second directions DR1 and DR2. In first and third rows R1 and R3, the first emission areas EA1 and the third emission areas EA3 may be alternately arranged in the first direction DR1, and in first and third columns C1 and C3, the first emission areas EA1 and the third emission areas EA3 may be alternately arranged in the second direction DR2.

The second emission areas EA2 may be spaced apart from one another in the first and second directions DR1 and DR2 and may be spaced apart from the first emission areas EA1 and the third emission areas EA3 in a fourth direction DR4 or a fifth direction DR5. The second emission areas EA2 may be repeatedly arranged in the first and second directions DR1 and DR2, and the second emission areas EA2 and the first emission areas EA1, or the second emission areas EA2 and the third emission areas EA3, may be alternately arranged in the fourth direction DR4 or the fifth direction DR5. In second and fourth rows R2 and R4, the second emission areas EA2 may be repeatedly arranged in the first direction DR1, and in second and fourth columns C2 and C4, the second emission areas EA2 may be repeatedly arranged in the second direction DR2.

The first emission areas EA1, the second emission areas EA2, and the third emission areas EA3 may be defined by a plurality of openings (OPE1, OPE2, and OPE3), which are formed in a bank structure (“BNS” of FIG. 6) of the light-emitting element layer EML. In an embodiment, for example, the first emission areas EA1 may be defined by first openings OPEL of the bank structure BNS, the second emission areas EA2 may be defined by second openings OPE2 of the bank structure BNS, and the third emission areas EA3 may be defined by third openings OPE3 of the bank structure BNS.

The size of the emission areas (EA1, EA2, and EA3) may vary depending on the size of the openings (OPE1, OPE2, and OPE3) of the bank structure. The intensity of light emitted from the emission areas (EA1, EA2, and EA3) may vary depending on the size of the emission areas (EA1, EA2, and EA3), and the color of a screen displayed by the display device 10 or the electronic device 1 may be controlled by controlling the size of the emission areas (EA1, EA2, and EA3). The first, second, and third emission areas EA1, EA2, and EA3 may have the same size. In the example of FIG. 6 (FIG. 5?), the first, second, and third emission areas EA1, EA2, and EA3 may have the same size or diameter.

However, the disclosure is not limited thereto. The size of the emission areas (EA1, EA2, and EA3) may be variously modified or controlled freely in accordance with a screen color required of the display device 10 or the electronic device 1. The size of the emission areas (EA1, EA2, and EA3) may be associated with the efficiency and the life of light-emitting elements (ED1, ED2, and ED3) and may be in a tradeoff relationship with the reflection of external light. The size of the emission areas (EA1, EA2, and EA3) may be controlled in consideration of all the above. In an embodiment, for example, the third emission areas EA3 may be larger in size than the first emission areas EA1 and the second emission areas EA2, and the first emission areas EA1 may be larger in size than the second emission areas EA2.

In an embodiment, as shown in FIG. 5, one first emission area EA1, two second emission areas EA2, and one third emission area EA3 may form one pixel group. Each pixel group may include emission areas (EA1, EA2, and EA3) that emit light of different colors and may thus be able to display white gradation, but the disclosure is not limited thereto. The combination of emission areas (EA1, EA2, and EA3) forming each pixel group may vary depending on the layout of the emission areas (EA1, EA2, and EA3) and the colors of beams of light emitted from the emission areas (EA1, EA2, and EA3).

The display device 10 may include a plurality of color filters (CF1, CF2, and CF3), which are disposed in the emission areas (EA1, EA2, and EA3). The color filters (CF1, CF2, and CF3) may be disposed to correspond to the emission areas (EA1, EA2, and EA3). In an embodiment, for example, the color filters (CF1, CF2, and CF3) may be disposed in a plurality of opening holes (OPT1, OPT2, and OPT3) of a light-blocking layer BM, which are disposed to correspond to the emission areas (EA1, EA2, and EA3) or the openings (OPE1, OPE2, and OPE3). The opening holes (OPT1, OPT2, and OPT3) of the light-blocking layer BM may be formed to overlap with the openings (OPE1, OPE2, and OPE3) and may form light-output areas that output light emitted from the emission areas (EA1, EA2, and EA3). The color filters (CF1, CF2, and CF3) may have a larger area than the openings (OPE1, OPE2, and OPE3) and may completely cover the light-output areas formed by the opening holes (OPT1, OPT2, and OPT3) of the light-blocking layer BM.

The color filters (CF1, CF2, and CF3) may include first color filters CF1, second color filters CF2, and third color filters CF3, which are disposed to correspond to different emission areas (EA1, EA2, and EA3). The color filters (CF1, CF2, and CF3) may include a pigment or dye capable of absorbing light of all wavelength ranges except for a particular wavelength range and may be disposed to correspond to the colors of beams of light emitted from the emission areas (EA1, EA2, and EA3). In an embodiment, for example, the first color filters CF1 may be disposed to overlap with the first emission areas EA1 and may be red color filters capable of transmitting only the first light, which is red light, therethrough. In an embodiment, for example, the second colors filter CF2 may be disposed to overlap with the second emission areas EA2 and may be green color filters capable of transmitting only the second light, which is green light, therethrough, and the third color filters CF3 may be disposed to overlap with the third emission areas EA3 and may be blue color filters capable of transmitting only the third light, which is blue light, therethrough.

The color filters (CF1, CF2, and CF3), like the emission areas (EA1, EA2, and EA3), may be arranged in a PenTile™ fashion, for example, in a diamond PenTile™ fashion. In an embodiment, for example, the first color filters CF1 and the third color filters CF3 may be alternately arranged in the first and second directions DR1 and DR2. In first and third rows R1 and R3, the first color filters CF1 and the third color filters CF3 may be alternately arranged in the first direction DR1, and in first and third columns C1 and C3, the first color filters CF1 and the third color filters CF3 may be alternately arranged in the second direction DR2.

The second color filters CF2 may be spaced apart from one another in the first and second directions DR1 and DR2 and may be spaced apart from the first color filters CF1 and the third color filters CF3 in the fourth direction DR4 or the second direction DR5. The second color filters CF2 may be repeatedly arranged in the first and second directions DR1 and DR2, and the second color filters CF2 and the first color filters CF1, or the second color filters CF2 and the third color filters CF2, may be alternately arranged in the fourth direction DR4 or the fifth direction DR5. In second and fourth rows R2 and R4, the second color filters CF2 may be repeatedly arranged in the first direction DR1, and in second and fourth columns C2 and C4, the second color filters CF2 may be repeatedly arranged in the second direction DR2.

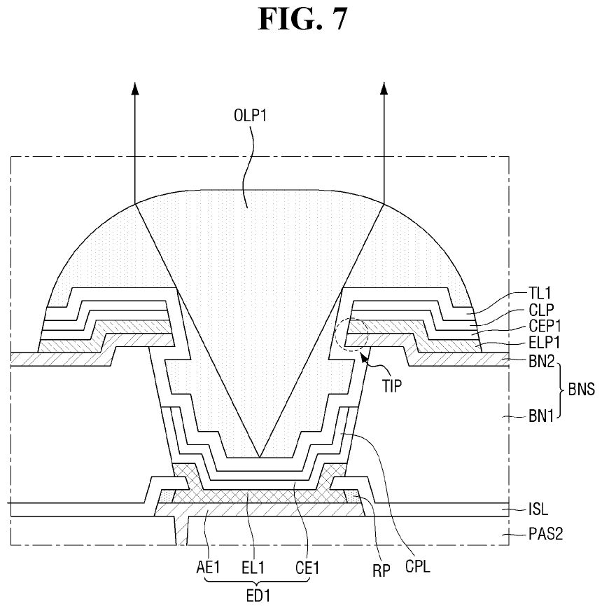

FIG. 6 is a cross-sectional view illustrating part of the display device of FIG. 2. FIG. 7 is an enlarged cross-sectional view illustrating a first emission area of FIG. 6. FIG. 6 illustrates the substrate SUB, the TFT layer TFTL, the light-emitting element layer EML, the thin-film encapsulation layer TFEL, the touch sensing layer TSU, and the color filter layer CFL of the display layer DU. FIG. 7 illustrates a first light-emitting element ED1, which is disposed in the first emission area EA1 of FIG. 6, and part of the bank structure BNS around the first light-emitting element ED1.

Referring to FIGS. 6 and 7 and further to FIG. 5, in an embodiment, the display panel 100 of the display device 10 may include the display layer DU. The display layer DU may include the substrate SUB, the TFT layer TFTL, the light-emitting element layer EML, and the thin-film encapsulation layer TFEL. The display panel 100 may include the light-blocking layer BM, which is disposed on the thin-film encapsulation layer TFEL, and the color filters (CF1, CF2, and CF3) of the color filter layer CFL may be disposed on the light-blocking layer BM.

The substrate SUB may be a base substrate or a base member. The substrate SUB may be a flexible substrate that is bendable, foldable, or rollable. In an embodiment, for example, the substrate SUB may include a polymer resin such as PI, but the disclosure is not limited thereto. In an alternative embodiment, for example, the substrate SUB may include a glass or metal material.

The TFT layer TFTL may include a first buffer layer BF1, a lower metal layer BML, a second buffer layer BF2, a first TFT TFT1, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing the infiltration of the air or moisture. In an embodiment, for example, the first buffer layer BF1 may include a plurality of inorganic films that are stacked.

The lower metal layer BML, which corresponds to a first conductive layer of the display panel 100, may be disposed on the first buffer layer BF1. In an embodiment, for example, the lower metal layer BML may be formed as a single layer or a multilayer, each layer including vanadium (V), molybdenum (Mo), aluminum (Al), chromium (Cr), gold (Au), titanium (Ti), nickel (Ni), neodymium (Nd), copper (Cu), or an alloy thereof, but the disclosure is not limited thereto.

The second buffer layer BF2 may cover the first buffer layer BF1 and the lower metal layer BML. The second buffer layer BF2 may include an inorganic film capable of preventing the infiltration of the air or moisture. In an embodiment, for example, the second buffer layer BF2 may include a plurality of inorganic films that are stacked.

The first TFT TFT1 may be disposed on the second buffer layer BF2 and may form the pixel circuit of a pixel. In an embodiment, for example, the first TFT TFT1 may be a driving transistor or a switching transistor. The first TFT TFT1 may include a semiconductor layer ACT, a source electrode SE, a drain electrode DE, and a gate electrode GE.

Semiconductor layers ACT may be disposed on the second buffer layer BF2. The semiconductor layers ACT may overlap the lower metal layer BML and gate electrodes GE in the thickness direction and may be insulated from the gate electrodes GE by the gate insulating layer GI. Parts of the semiconductor layers ACT may be transformed into conductors and may thus form source electrodes SE and drain electrodes DE.

The gate electrodes GE may be disposed on the gate insulating layer GI. The gate electrodes GE may overlap the semiconductor layers ACT with the gate insulating layer GI interposed therebetween.

The gate insulating layer GI may be disposed on the semiconductor layers ACT. In an embodiment, for example, the gate insulating layer GI may cover the semiconductor layers ACT and the second buffer layer BF2 and may insulate the semiconductor layers ACT and the gate electrodes GE. The gate insulating layer GI may be provided with contact holes defined therein, and the first connection electrodes CNE1 may be disposed through the gate insulating layer GI via the contact holes.

A first interlayer insulating layer ILD1 may cover the gate electrodes GE and the gate insulating layer GI. The first interlayer insulating layer ILD1 may be provided with contact holes defined therein, and the first connection electrodes CNE1 may be disposed through the first interlayer insulating layer ILD1 via the contact holes. The contact holes of the first interlayer insulating layer ILD1 may be connected to the contact holes of the gate insulating layer GI and contact holes of a second interlayer insulating layer ILD2.

The capacitor electrodes CPE may be disposed on the first interlayer insulating layer ILD1. The capacitor electrodes CPE may overlap the gate electrodes GE in the thickness direction. The capacitor electrodes CPE and the gate electrodes GE may form capacitors.

The second interlayer insulating layer ILD2 may cover the capacitor electrodes CPE and the first interlayer insulating layer ILD1. The second interlayer insulating layer ILD2 may be provided with contact holes defined therein, and the first connection electrodes CNE1 may be disposed through the second interlayer insulating layer ILD2 via the contact holes. The contact holes of the second interlayer insulating layer ILD2 may be connected to the contact holes of the first interlayer insulating layer ILD1 and the contact holes of the gate insulating layer GI.

The first connection electrodes CNE1 may be disposed on the second interlayer insulating layer ILD2. One of the first connection electrode CNE1 may be electrically connected to the drain electrode DE of the first TFT TFT1 and one of the second connection electrodes CNE2. The first connection electrodes CNE1 may be inserted in the contact holes of each of the second interlayer insulating layer ILD2, the first interlayer insulating layer ILD1, and the gate insulating layer GI and may thus be in contact with the drain electrodes DE.

The first passivation layer PAS1 may cover the first connection electrode CNE1 and the second interlayer insulating layer ILD2. The first passivation layer PAS1 may protect the first TFT TFT1. The first passivation layer PAS1 may include a contact hole that is penetrated by the second connection electrode CNE2.

The second connection electrodes CNE2 may be disposed on the first passivation layer PAS1. The second connection electrodes CNE2 may electrically connect the first connection electrodes CNE1 and anodes (AE1, AE2, and AE3) of light-emitting elements (ED1, ED2, and ED3). The second connection electrodes CNE2 may be inserted in the contact holes of the first passivation layer PAS1 and may be in contact with the first connection electrodes CNE1.

The second passivation layer PAS2 may cover the second connection electrode CNE2 and the first passivation layer PAS1. The second passivation layer PAS2 may include contact holes that are penetrated by the anodes (AE1, AE2, and AE3).

The light-emitting element layer EML may be disposed on the TFT layer TFTL. The light-emitting element layer EML may include the light-emitting elements (ED1, ED2, and ED3) and the bank structure BNS. The light-emitting elements (ED1, ED2, and ED3) may include the anodes (AE1, AE2, and AE3), light-emitting layers (EL1, EL2, and EL3), and cathodes (CE1, CE2, and CE3).

The display device 10 may include a plurality of emission areas (EA1, EA2, and EA3), which are disposed in the display area DA. The emission areas (EA1, EA2, and EA3) may include first, second, and third emission areas EA1, EA2, and EA3, which emit light of different colors, respectively. The first, second, and third emission areas EA1, EA2, and EA3 may emit red light, green light, and blue light, respectively, and the colors of beams of light emitted from the emission areas (EA1, EA2, and EA3) may vary depending on the types of the light-emitting elements (ED1, ED2, and ED3) in the light-emitting element layer EML. In an embodiment, for example, the first emission area EA1 may emit first light, which is red light, the second emission area EA2 may emit second light, which is green light, and the third emission area EA3 may emit third light, which is blue light. However, the disclosure is not limited thereto.

The first, second, and third emission areas EA1, EA2, and EA3 may be defined by a plurality of openings (OPE1, OPE2, and OPE3), which are formed in the bank structure BNS of the light-emitting element layer EML. In an embodiment, for example, the first emission area EA1 may be defined by a first opening OPEL of the bank structure BNS, the second emission area EA2 may be defined by a second opening OPE2 of the bank structure BNS, and the third emission area EA3 may be defined by a third opening OPE3 of the bank structure BNS.

The first, second, and third emission areas EA1, EA2, and EA3 may have a same size (or planar area) as each other. In an embodiment, for example, the openings (OPE1, OPE2, and OPE3) of the bank structure BNS may have a same diameter as each other, and the first, second, and third emission areas EA1, EA2, and EA3 may have a same size as each other. However, the disclosure is not limited thereto. Alternatively, the first, second, and third emission areas EA1, EA2, and EA3 may have different sizes from each other. In an embodiment, for example, the second emission area EA2 may be larger in size than the first and third emission areas EA1 and EA3, and the third emission area EA3 may be larger in size than the first emission area EA1. The intensity of light emitted by the emission areas (EA1, EA2, and EA3) may vary depending on the size of the emission areas (EA1, EA2, and EA3), and screen colors displayed by the display device or the electronic device 1 may be controlled by controlling the size of the emission areas (EA1, EA2, and EA3). FIG. 5 illustrates that the first, second, and third emission areas EA1, EA2, and EA3 have the same size, but the disclosure is not limited thereto. The size of the emission areas (EA1, EA2, and EA3) may be freely controlled in accordance with the screen colors required by the display device 10 or the electronic device 1. Also, the size of the emission areas (EA1, EA2, and EA3) may be related to the efficiency and lifetime of the light-emitting elements (ED1, ED2, and ED3) and may have a trade-off relation with the reflection of external light. The size of the emission areas (EA1, EA2, and EA3) may be controlled in consideration of all the above.

In an embodiment of the display device 10, one first emission area EA1, one second emission area EA2, and one third emission area EA3, which are disposed adjacent to one another, may form or collectively define one pixel group. One pixel group may include emission areas (EA1, EA2, and EA3) that emit light of different colors, respectively, and may thus be able to display white gradation. However, the disclosure is not limited thereto. That is, the combination of emission areas (EA1, EA2, and EA3) forming each pixel group may vary depending on the layout or arrangement of the emission areas (EA1, EA2, and EA3) and the colors of light emitted from the emission areas (EA1, EA2, and EA3).

The display device 10 may include a plurality of light-emitting elements (ED1, ED2, and ED3), which are disposed in different emission areas (EA1, EA2, and EA3). The light-emitting elements (ED1, ED2, and ED3) may include first, second, and third light-emitting elements (ED1, ED2, and ED3)1, ED2, and ED3, which are disposed in the first, second, and third emission areas ED1, ED2, and ED3, respectively. The light-emitting elements (ED1, ED2, and ED3) may include the anodes (AE1, AE2, and AE3), the light-emitting layers (EL1, EL2, and EL3), and the cathodes (CE1, CE2, and CE3) and may emit light of different colors depending on the material of the light-emitting layers (EL1, EL2, and EL3). In an embodiment, for example, the first light-emitting element ED1, which is disposed in the first emission area EA1, may emit the first light, i.e., red light, the second light-emitting element ED2, which is disposed in the second emission area EA2, may emit the second light, i.e., green light, and the third light-emitting element ED3, which is disposed in the third emission area EA3, may emit the third light, i.e., blue light. The first, second, and third emission areas EA1, EA2, and EA3, which form one pixel together, may include the first, second, and third light-emitting elements (ED1, ED2, and ED3)1, ED2, and ED3, respectively, which emit light of different colors, and may thus be able to display white gradation.

The anodes (AE1, AE2, and AE3) may be disposed on the second passivation layer PAS2. The anodes (AE1, AE2, and AE3) may be disposed to overlap with first, second, and third openings OPE1, OPE2 and OPE3 of the bank structure BNS. The anodes (AE1, AE2, and AE3) may be electrically connected to the drain electrodes DE via the first connection electrodes CNE1 and the second connection electrodes CNE2.

The anodes (AE1, AE2, and AE3) may be disposed in the emission areas (EA1, EA2, and EA3). The anodes (AE1, AE2, and AE3) may include a first anode AE1, which is disposed in the first emission area EA1, a second anode AE2, which is disposed in the second emission area EA2, and a third anode AE3, which is disposed in the third emission area EA3. The first, second, and third anodes AE1, AE2, and AE3 may be spaced apart from one another on the second passivation layer PAS2. The anodes (AE1, AE2, and AE3) may be disposed in different emission areas (EA1, EA2, and EA3) and may thus form light-emitting elements (ED1, ED2, and ED3) that emit light of different colors, respectively.

An inorganic insulating layer ISL may be disposed on the second passivation layer PAS2 and the anodes (AE1, AE2, and AE3). The inorganic insulating layer ISL may be disposed on the second passivation layer PAS2 and may partially overlap the anodes (AE1, AE2, and AE3) to expose parts of the top surfaces of the anodes (AE1, AE2, and AE3). In an embodiment, for example, the inorganic insulating layer ISL may expose the anodes (AE1, AE2, and AE3) in areas that overlap the openings (OPE1, OPE2, and OPE3) of the bank structure BNS, and the light-emitting layers (EL1, EL2, and EL3) may be disposed directly on the anodes (AE1, AE2, and AE3). The inorganic insulating layer ISL may include an inorganic insulating material. In an embodiment, for example, the inorganic insulating layer ISL may include aluminum oxide, titanium oxide, tantalum oxide, hafnium oxide, zinc oxide, silicon oxide, silicon nitride, and/or silicon oxynitride.

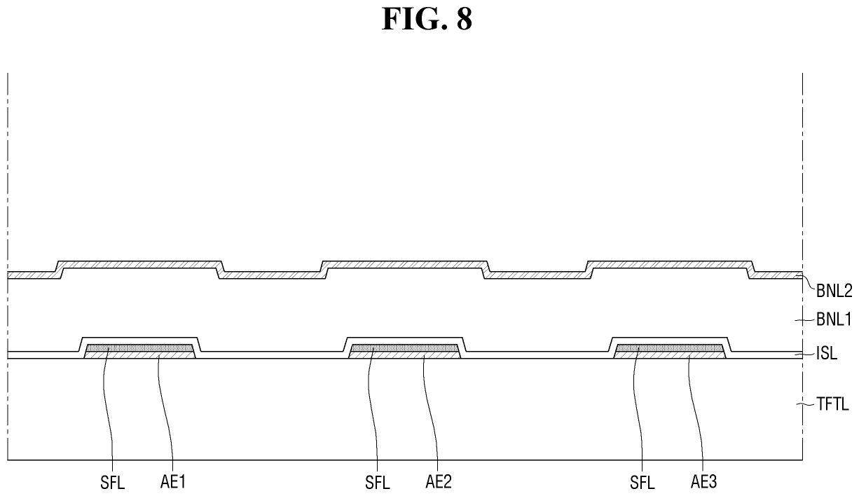

The inorganic insulating layer ISL may be disposed on the anodes (AE1, AE2, and AE3) and may be spaced apart from the top surfaces of the anodes (AE1, AE2, and AE3). The inorganic insulating layer ISL may not be in direct contact with the anodes (AE1, AE2, and AE3), partially overlapping the anodes (AE1, AE2, and AE3), and parts of the light-emitting layers (EL1, EL2, and EL3) of the light-emitting elements (ED1, ED2, and ED3) may be disposed between the inorganic insulating layer ISL and the anodes (AE1, AE2, and AE3). During the fabrication of the display device 10, a sacrificial layer (“SFL” of FIG. 8) may be disposed on the anodes (AE1, AE2, and AE3) before the formation of the inorganic insulating layer ISL. The inorganic insulating layer ISL may be initially disposed to cover part of the sacrificial layer, and may be spaced apart from the top surfaces of the anodes (AE1, AE2, and AE3) in response to the sacrificial layer being removed. The inorganic insulating layer ISL may protrude from residual patterns RP toward the inside of openings (OPE1, OPE2, and OPE3). During deposition processes for forming the light-emitting layers (EL1, EL2, and EL3), the material of the light-emitting layers (EL1, EL2, and EL3) may fill the gaps between the inorganic insulating layer ISL and the anodes (AE1, AE2, and AE3), and the inorganic insulating layer ISL may be disposed in part on the light-emitting layers (EL1, EL2, and EL3). In such an embodiment, the inorganic insulating layer ISL may be in direct contact with side surfaces of each of the anodes (AE1, AE2, and AE3).

The display device 10 may include the bank structure BNS, which is disposed on the TFT layer TFTL or the substrate SUB and includes the openings (OPE1, OPE2, and OPE3). The bank structure BNS may have a structure in which a plurality of bank layers including different materials from each other, i.e., first and second bank layers BN1 and BN2, are sequentially stacked, and may be provided with the openings (OPE1, OPE2, and OPE3) defined therein to define the emission areas (EA1, EA2, and EA3). The light-emitting elements (ED1, ED2, and ED3) of the display device 10 may be disposed to overlap the openings (OPE1, OPE2, and OPE3) of the bank structure BNS.

The bank structure BNS may include a first bank layer BN1, which is disposed on the inorganic insulating layer ISL, and a second bank layer BN2, which is disposed on the first bank layer BN1.

In an embodiment, as shown in FIG. 7, the first and second bank layers BN1 and BN2 may include different metal materials from each other, and the bank structure BNS may include tips TIP, which are parts of the second bank layer BN2 that protrude beyond the first bank layer BN toward a center of the openings (OPE1, OPE2, and OPE3). The sides (side surfaces or side walls) of the first bank layer BN1 may be depressed inwardly from the corresponding sides of the second bank layer BN2, respectively. The first bank layer BN1 may be thicker than the second bank layer BN2. The second bank layer BN2 may be relatively thin, and the tips TIP may be formed in the second bank layer BN2 during the formation of the second bank layer BN2. As the second bank layer BN2 is protruded beyond the first bank layer BN1 toward the openings (OPE1, OPE2, and OPE3), undercuts (or undercut structures) may be formed in the openings (OPE1, OPE2, and OPE3) of the bank structure BNS, below the tips TIP of the second bank layer BN2.

The structure of the bank structure BNS may originate due to the first and second bank layers BN1 and BN2 having different materials, respectively, and thus being etched at different rates, respectively. The second bank layer BN2 may include a material that is etched slower than the first bank layer BN1, and the first bank layer BN1 may be more etched than the second bank layer BN2 during the formation of the openings (OPE1, OPE2, and OPE3) so that undercuts may be formed below the tips TIP of the second bank layer BN2. The first bank layer BN1 may include a metal material with high electrical conductivity, and the second bank layer BN2 may include a metal material with low reflectance. In an embodiment, for example, the first bank layer BN1 may include Al, and the second bank layer BN2 may include Ti. The bank layer BNS may have a structure in which Al and Ti layers are stacked on the inorganic insulating layer ISL, and the tips TIP may be formed in the Ti layer, i.e., the second bank layer BN2.

The bank structure BNS may be provided with the openings (OPE1, OPE2, and OPE3), which define the emission areas (EA1, EA2, and EA3), respectively, and the light-blocking layer BM may be disposed on the bank structure BNS. The uppermost layer of the bank structure BNS may include a material with low reflectance and may thus be able to reduce the reflection of external light. Also, the first bank layer BN1 of the bank structure BNS may be electrically connected to the cathodes (CE1, CE2, and CE3) of the light-emitting elements (ED1, ED2, and ED3). The light-emitting elements (ED1, ED2, and ED3), which are disposed in the emission areas (EA1, EA2, and EA3), may not be directly connected to the cathodes (CE1, CE2, and CE3), but may be electrically connected to the cathodes (CE1, CE2, and CE3) through the first bank layer BN1 of the bank structure BNS.

In an embodiment, during the fabrication of the display device 10, mask processes may be used to form a pixel-defining film, which defines the emission areas (EA1, EA2, and EA3), of an organic material and to form the light-emitting layers (EL1, EL2, and EL3) in the emission areas (EA1, EA2, and EA3). In such an embodiment, where the mask processes are performed, the display device 10 may be desired to have a structure for mounting masks or an undesirably large-size non-display area NDA to control dispersion in accordance with the mask processes. If the mask processes are minimized, undesired components such as, for example, the structure for mounting masks, may not be provided in the display device 10, and the size of the non-display area NDA for the control of dispersion control can be minimized.

In an embodiment, the display device 10 may include the bank structure BNS, which defines the light emitting areas EA1, EA2, and EA3, and the bank structure BNS may be formed by deposition and etching processes without using a mask. In such an embodiment, as the bank structure BNS includes the first and second bank layers BN1 and BN2, which include different metal materials, respectively, and the inner sidewalls of the openings (OPE1, OPE2, and OPE3) include tips TIP, different layers can be formed separately in different emission areas (EA1, EA2, and EA3), simply through deposition. In an embodiment, for example, even if the light-emitting layers (EL1, EL2, and EL3) and the cathodes (CE1, CE2, and CE3) of the light-emitting elements (ED1, ED2, and ED3) are formed by deposition processes not using masks, deposited materials for forming the light-emitting layers (EL1, EL2, and EL3) and the cathodes (CE1, CE2, and CE3) of the light-emitting elements (ED1, ED2, and ED3) may not be connected, but disconnected between the openings (OPE1, OPE2, and OPE3) by the tips TIP of the second bank layer BN2, which are formed on the inner sidewalls defining the openings (OPE1, OPE2, and OPE3). After the formation of a particular layer through deposition on the entire surface of the display device 10, the particular layer may be etched away from undesignated areas. In this manner, different layers can be formed in different emission areas (EA1, EA2, and EA3), respectively. Different light-emitting elements (ED1, ED2, and ED3) can be formed in different emission areas (EA1, EA2, and EA3) through deposition and etching, without using a mask process, undesired components can be omitted from the display device, and the size of the non-display area NDA can be minimized.

A first encapsulation layer TFE1 of the thin-film encapsulation layer TFEL may be disposed on the cathodes (CE1, CE2, and CE3) of the light-emitting elements (ED1, ED2, and ED3). The first encapsulation layer TFE1 may include first, second, and third inorganic layers TL1, TL2, and TL3, which are disposed on the first, second, and third light-emitting elements ED1, ED2, and ED3, respectively. The first, second, and third inorganic layers TL1, TL2, and TL3 may initially be formed on the entire surface of the bank structure BNS, may be disposed later to cover only the light-emitting elements (ED1, ED2, and ED3), organic patterns (ELP1, ELP2, and ELP3), and electrode patterns (CEP1, CEP2, and CEP3), in the emission areas (EA1, EA2, and EA3), and may not be disposed between the emission areas (EA1, EA2, and EA3). In such an embodiment, the first, second, and third inorganic layers TL1, TL2, and TL3 may initially be formed to fully cover the bank structure BNS and may be partially patterned later.

The display device 10 may include patterns that are traces of the light-emitting elements (ED1, ED2, and ED3) on the bank structure BNS. The patterns may be formed during the formation of the light-emitting layers (EL1, EL2, and EL3) and the cathodes (CE1, CE2, and CE3) of the light-emitting elements (ED1, ED2, and ED3) and may remain on the bank structure BNS. These patterns and the structures of the light-emitting layers (EL1, EL2, and EL3) and the cathodes (CE1, CE2, and CE3) will hereinafter be described.

The light-emitting layers (EL1, EL2, and EL3) may be disposed on the anodes (AE1, AE2, and AE3). The light-emitting layers (EL1, EL2, and EL3) may be organic light-emitting layers including or formed of an organic material and may be formed on the anodes (AE1, AE2, and AE3) through deposition. The light-emitting layers (EL1, EL2, and EL3) may apply a predetermined voltage to the anodes (AE1, AE2, and AE3) of the light-emitting elements (ED1, ED2, and ED3), and when the cathodes (CE1, CE2, and CE3) of the light-emitting elements (ED1, ED2, and ED3) receive a common voltage or a cathode voltage, holes and electrons may move to the light-emitting elements (ED1, ED2, and ED3) through a hole transport layer and an electron transport layer and may combine together in the light-emitting layers (EL1, EL2, and EL3) to emit light.

The light-emitting layers (EL1, EL2, and EL3) may include first, second, and third light-emitting layers EL1, EL2, and EL3, which are disposed in different emission areas (EA1, EA2, and EA3), respectively. The first light-emitting layer EL1 may be disposed on the first anode AE1, in the first emission area EA1, the second light-emitting layer EL2 may be disposed on the second anode AE1, in the second emission area EA2, and the third light-emitting layer EL3 may be disposed on the third anode AE3, in the third emission area EA3. The first, second, and third light-emitting layers EL1, EL2, and EL3 may be the light-emitting layers of the first, second, and third light-emitting elements ED1, ED2, and ED3. The first light-emitting layer EL1 may be a light-emitting layer that emits the first light, i.e., red light, the second light-emitting layer EL2 may be a light-emitting layer that emits the second light, i.e., green light, and the third light-emitting layer EL3 may be a light-emitting layer that emits the third light, i.e., blue light.

The light-emitting layers (EL1, EL2, and EL3) of the light-emitting elements (ED1, ED2, and ED3) may be disposed in part between the inorganic insulating layer ISL and the anodes (AE1, AE2, and AE3). The inorganic insulating layer ISL may be disposed on the anodes (AE1, AE2, and AE3) and may be spaced apart from the top surfaces of the anodes (AE1, AE2, and AE3). The deposition of the light-emitting layers (EL1, EL2, and EL3) may be performed diagonally (or in an oblique direction), rather than perpendicularly, with respect to the top surface of the substrate SUB. As a result, the light-emitting layers (EL1, EL2, and EL3) may be disposed on parts of the top surfaces of the anodes (AE1, AE2, and AE3) that are exposed by the openings (OPE1, OPE2, and OPE3) of the bank structure BNS, and may fill the spaces between the inorganic insulating layer ISL and the anodes (AE1, AE2, and AE3).

In an embodiment, as described above, during the fabrication of the display device 10, the sacrificial layer SFL of FIG. 8 may be disposed between the inorganic insulating layer ISL and the anodes (AE1, AE2, and AE3), and the light-emitting layers (EL1, EL2, and EL3) may be disposed in regions from which parts of the sacrificial layer are removed. As a result, the bottom surface of the inorganic insulating layer ISL may be spaced apart from the anodes (AE1, AE2, and AE3). The sacrificial layer may remain between the inorganic insulating layer ISL and the anodes (AE1, AE2, and AE3) as residual patterns RP. The regions between the inorganic insulating layer ISL and the anodes (AE1, AE2, and AE3) may be filled with the residual patterns RP and the light-emitting layers (EL1, EL2, and EL3).

The cathodes (CE1, CE2, and CE3) may be disposed on the light-emitting layers (EL1, EL2, and EL3). The cathodes (CE1, CE2, and CE3) may include a transparent conductive material and may thus output light generated by the light-emitting layers (EL1, EL2, and EL3). The cathodes (CE1, CE2, and CE3) may receive a common voltage or a low-potential voltage. As the anodes (AE1, AE2, and AE3) receive a voltage corresponding to a data voltage and the cathodes (CE1, CE2, and CE3) receive a low-potential voltage, the difference in electric potential is formed between the anodes (AE1, AE2, and AE3) and the cathodes (CE1, CE2, and CE3), and as a result, the light-emitting layers (EL1, EL2, and EL3) may emit light.

The cathodes (CE1, CE2, and CE3) may include first, second, and third cathodes CE1, CE2, and CE3, which are disposed in different emission areas (EA1, EA2, and EA3), respectively. The first cathode CE1 may be disposed on the first light-emitting layer EL1, in the first emission area EA1, the second cathode CE2 may be disposed on the second light-emitting layer EL2, in the second emission area EA2, and the third cathode CE3 may be disposed on the third light-emitting layer EL3, in the third emission area EA3.

Parts of the cathodes (CE1, CE2, and CE3) of the light-emitting elements (ED1, ED2, and ED3) may be disposed on the sides of the first bank layer BN1 of the bank structure BNS. The cathodes (CE1, CE2, and CE3), like the light-emitting layers (EL1, EL2, and EL3), may be formed by deposition. Deposition processes for forming the cathodes (CE1, CE2, and CE3) may be performed such that an electrode material for forming the cathodes (CE1, CE2, and CE3) may be deposited diagonally, rather than perpendicularly, with respect to the top surface of the substrate SUB. Accordingly, the cathodes (CE1, CE2, and CE3) may be disposed on the sides of the first bank layer BN1, below the tips TIP of the second bank layer BN2 of the bank structure BNS. The cathodes (CE1, CE2, and CE3) may be in direct contact with the sides of the first bank layer BN1. The cathodes (CE1, CE2, and CE3) of different light-emitting elements (ED1, ED2, and ED3) may be in direct contact with the first bank layer BN1 of the bank structure BNS and may be electrically connected to one another. The cathodes (CE1, CE2, and CE3), unlike the anodes (AE1, AE2, and AE3), may not be separate between multiple pixels, but may be in common electrically for all pixels.

The contact areas of the cathodes (CE1, CE2, and CE3) and the sides of the first bank layer BN1 may be greater than the contact areas of the light-emitting layers (EL1, EL2, and EL3) and the sides of the first bank layer BN1. The material of the cathodes (CE1, CE2, and CE3) and the material of the light-emitting layers (EL1, EL2, and EL3) may be deposited diagonally, rather than perpendicularly, with respect to the top surface of the substrate SUB, and the contact areas of the cathodes (CE1, CE2, and CE3) and the sides of the first bank layer BN1 and the contact areas of the light-emitting layers (EL1, EL2, and EL3) and the sides of the first bank layer BN1 may vary depending on the inclinations at which the material of the cathodes (CE1, CE2, and CE3) and the material of the light-emitting layers (EL1, EL2, and EL3) are deposited. The material of the cathodes (CE1, CE2, and CE3) may be deposited at a greater inclination than the material of the light-emitting layers (EL1, EL2, and EL3). The cathodes (CE1, CE2, and CE3) may be deposited over larger areas of the sidewalls defining the openings (OPE1, OPE2, and OPE3) and to greater heights in the openings (OPE1, OPE2, and OPE3) than the light-emitting layers (EL1, EL2, and EL3). The larger the contact areas of the cathodes (CE1, CE2, and CE3) of the light-emitting elements (ED1, ED2, and ED3) and the first bank layer BN1, the less the resistance of cathodes formed by the cathodes (CE1, CE2, and CE3) of the light-emitting elements (ED1, ED2, and ED3) and the first bank layer BN1. Accordingly, it may be desired that the cathodes (CE1, CE2, and CE3) of the light-emitting elements (ED1, ED2, and ED3) are electrically connected to the first bank layer BN1 by a relatively large contact area with the first bank layer BN1.

A capping layer CPL may be disposed on the cathodes (CE1, CE2, and CE3). The capping layer CPL may include an inorganic insulating material and may cover the light-emitting elements (ED1, ED2, and ED3) and patterns on the bank structure BNS. The capping layer CPL may prevent the light-emitting elements (ED1, ED2, and ED3) from being damaged by external air, and may prevent the patterns on the bank structure BNS from being peeled off during the fabrication of the display device 10. The capping layer CPL may include aluminum oxide, titanium oxide, tantalum oxide, hafnium oxide, zinc oxide, silicon oxide, silicon nitride, and/or silicon oxynitride.

The display device 10 may include the organic patterns (ELP1, ELP2, and ELP3, which include same materials as the light-emitting layers (EL1, EL2, and EL3), respectively, and are disposed on the bank structure BNS. As the light-emitting layers (EL1, EL2, and EL3) are formed by a deposition process of depositing the corresponding material on the entire surface of the display device 10, the material of the light-emitting layers (EL1, EL2, and EL3) may be deposited not only in the openings (OPE1, OPE2, and OPE3) of the bank structure BNS, but also on the bank structure BNS.

In an embodiment, for example, the display device 10 may include the organic patterns (ELP1, ELP2, and ELP3), which are disposed on the bank structure BNS. The organic patterns (ELP1, ELP2, and ELP3) may include first, second, and third organic patterns ELP1, ELP2, and ELP3, which are disposed on the second bank layer BN2 of the bank structure BNS.

The first organic pattern ELP1 may include a same material as the first light-emitting layer EL1 of the first light-emitting element ED1. The second organic pattern ELP2 may include a same material as the second light-emitting layer EL2 of the second light-emitting element ED2. The third organic pattern ELP3 may include a same material as the third light-emitting layer EL3 of the third light-emitting element ED3. The organic patterns (ELP1, ELP2, and ELP3) may be formed by a same process as the light-emitting layers (EL1, EL2, and EL3).

The first, second, and third organic patterns ELP1, ELP2, and ELP3 may be disposed directly on the second bank layer BN2 of the bank structure BNS. The organic patterns (ELP1, ELP2, and ELP3) may be formed by same processes as the light-emitting layers (EL1, EL2, and EL3), respectively, to be disposed near the emission areas (EA1, EA2, and EA3), in which the light-emitting layers (EL1, EL2, and EL3) are disposed. In an embodiment, for example, the first organic pattern ELP1 may surround the first opening OPE1, near the first emission area EA1 or the first opening OPE1, and may be disposed on the second bank layer BN2. In an embodiment, for example, the second organic pattern ELP2 may surround the second opening OPE2, near the second emission area EA2 or the second opening OPE2, and may be disposed on the second bank layer BN2. In an embodiment, for example, the third organic pattern ELP3 may surround the third opening OPE3, near the third emission area EA3 or the third opening OPE3, and may be disposed on the second bank layer BN2.

As the bank structure BNS includes the tips TIP, the organic patterns (ELP1, ELP2, and ELP3) may be traces of the deposited material for forming the light-emitting layers (EL1, EL2, and EL3) that are disconnected from the light-emitting layers (EL1, EL2, and EL3) by the tips TIP of the bank structure BNS. The light-emitting layers (EL1, EL2, and EL3) may be formed in the openings (OPE1, OPE2, and OPE3) and may be disconnected from the organic patterns (ELP1, ELP2, and ELP3) by the tips TIP formed on the sidewalls defining each of the openings (OPE1, OPE2, and OPE3) of the bank structure BNS. As the light-emitting layers (EL1, EL2, and EL3) are formed by deposition without using a mask, the material of the light-emitting layers (EL1, EL2, and EL3) may be initially deposited on the entire bank structure BNS and may then be patterned around the emission areas (EA1, EA2, and EA3) or the openings (OPE1, OPE2, and OPE3), thereby obtaining the organic patterns (ELP1, ELP2, and ELP3).

The display device 10 may include the electrode patterns (CEP1, CEP2, and CEP3), which include a same material as the cathodes (CE1, CE2, and CE3) and are disposed on the bank structure BNS. As the cathodes (CE1, CE2, and CE3) are formed by a deposition process of depositing the corresponding material on the entire surface of the display device 10, the material of the cathodes (CE1, CE2, and CE3) may be deposited not only in the openings (OPE1, OPE2, and OPE3) of the bank structure BNS, but also on the bank structure BNS.

The display device 10 may include the electrode patterns (CEP1, CEP2, and CEP3), which are disposed on the bank structure BNS. The electrode patterns (CEP1, CEP2, and CEP3) may include first, second, and third electrode patterns CEP1, CEP2, and CEP3, which are disposed on the second bank layer BN2 of the bank structure BNS.

In an embodiment, for example, the first, second, and third electrode patterns CEP1, CEP2, and CEP3 may be disposed directly on the first, second, and third organic patterns ELP1, ELP2, and ELP3, respectively. The relationship between the electrode patterns (CEP1, CEP2, and CEP3) and the organic patterns (ELP1, ELP2, and ELP3) may be the same as the relationship between the cathodes (CE1, CE2, and CE3) and the light-emitting layers (EL1, EL2, and EL3) of the light-emitting elements (ED1, ED2, and ED3). The electrode patterns (CEP1, CEP2, and CEP3) may be traces of the deposited material for forming the cathodes (CE1, CE2, and CE3) that are disconnected from the cathodes (CE1, CE2, and CE3) by the tips TIP of the bank structure BNS. Due to the presence of the tips TIP of the bank structure BNS, the cathodes (CE1, CE2, and CE3) can be formed separately in different areas even by a deposition process without using a mask.

The display device 10 may include capping patterns CLP, which are disposed on the bank structure BNS. The capping patterns CLP may be disposed on the electrode patterns (CEP1, CEP2, and CEP3), which are disposed on the second bank layer BN2 of the bank structure BNS. The layout relationship between the capping patterns CLP and the electrode patterns (CEP1, CEP2, and CEP3) may be the same as the layout relationship between the capping layer CPL and the cathodes (CE1, CE2, and CE3) of the light-emitting elements (ED1, ED2, and ED3). The capping patterns CLP may be traces of the material of the capping layer CPL that remain by being disconnected from the capping layer CPL by the tips TIP of the bank structure BNS.

The organic patterns (ELP1, ELP2, and ELP3), the electrode patterns (CEP1, CEP2, and CEP3), and the capping patterns CLP may be disposed on the bank structure BNS to surround the emission areas (EA1, EA2, and EA3) or the openings (OPE1, OPE2, and OPE3). During the fabrication of the display device 10, stacks of the organic patterns (ELP1, ELP2, and ELP3), the electrode patterns (CEP1, CEP2, and CEP3), and the capping patterns CLP may be partially etched around the emission areas (EA1, EA2, and EA3), and as a result, the shape of the stacks of the organic patterns (ELP1, ELP2, and ELP3), the electrode patterns (CEP1, CEP2, and CEP3), and the capping patterns CLP may change. Accordingly, parts of the top surface of the second bank layer BN2 of the bank structure BNS may not be covered by the organic patterns (ELP1, ELP2, and ELP3), the electrode patterns (CEP1, CEP2, and CEP3), and the capping patterns CLP.

The thin-film encapsulation layer TFEL may be disposed on the light-emitting elements (ED1, ED2, and ED3) and the bank structure BNS and may cover the light-emitting elements (ED1, ED2, and ED3) and the bank structure BNS. The thin-film encapsulation layer TFEL may include at least one inorganic film and may prevent the infiltration of oxygen or moisture into the light-emitting element layer EML. The thin film-encapsulation layer TFEL may also include at least one organic film and may protect the light-emitting element layer EML from a foreign material such as dust.

The thin film-encapsulation layer TFEL may include first, second, and third encapsulation layers TFE1, TFE2, and TFE3, which are sequentially stacked. The first and third encapsulation layers TFEL and TFE3 may be inorganic encapsulation layers, and the second encapsulation layer TFE2, which is disposed between the first and third encapsulation layers TFE1 and TFE3, may be an organic encapsulation layer.

The first and third encapsulation layers TFEL and TFE3 may include an inorganic insulating material. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer material. The polymer material may include an acrylic resin, an epoxy resin, polyimide, or polyethylene. In an embodiment, for example, the second encapsulation layer TFE2 may include an acrylic resin, for example, polymethyl methacrylate or polyacrylic acid. The second encapsulation layer TFE2 may be formed by curing a monomer or applying a polymer.

The first encapsulation layer TFE1 may be disposed on the light-emitting elements (ED1, ED2, and ED3), on the patterns on the bank structure BNS, and on the bank structure BNS. The first encapsulation layer TFE1 may include the first, second, and third inorganic layers TL1, TL2, and TL3, which are disposed to correspond to different emission areas (EA1, EA2, and EA3).

The first, second, and third inorganic layers TL1, TL2, and TL3 may include an inorganic insulating material and may cover the light-emitting elements (ED1, ED2, and ED3). The first, second, and third inorganic layers TL1, TL2, and TL3 may prevent the light-emitting elements (ED1, ED2, and ED3) from being damaged by external air and may prevent the patterns on the bank structure BNS from being peeled off during the fabrication of the display device 10. The first, second, and third inorganic layers TL1, TL2, and TL3 may include aluminum oxide, titanium oxide, tantalum oxide, hafnium oxide, zinc oxide, silicon oxide, silicon nitride, and/or silicon oxynitride.

The first, second, and third inorganic layers TL1, TL2, and TL3 may be disposed to cover the organic patterns (ELP1, ELP2, and ELP3), the electrode patterns (CEP1, CEP2, and CEP3), and the capping patterns CLP. The first, second, and third inorganic layers TL1, TL2, and TL3 may be formed by chemical vapor deposition (CVD) and may thus be formed to have a uniform thickness along their respective underlying layers. In an embodiment, for example, the first, second, and third inorganic layers TL1, TL2, and TL3 may be thinly formed even below the undercuts formed by the tips TIP of the bank structure BNS.

The first inorganic layer TL1 may be disposed on the first light-emitting element ED1 and the first electrode pattern CEP1. The first inorganic layer TL1 may be disposed along the first light-emitting element ED1 and the first opening OPEL to cover the first light-emitting element ED1 and the first opening OPE1, and may also cover the first organic pattern ELP1, the first electrode pattern CEP1, and one of the capping patterns CLP. The first inorganic layer TL1 may not overlap the second and third openings OPE2 and OPE3, and may be disposed only in the first opening OPE1 and on part of the bank structure BNS around the first opening OPE1.

The second inorganic layer TL2 may be disposed on the second light-emitting element ED2 and the second electrode pattern CEP2. The second inorganic layer TL2 may be disposed along the second light-emitting element ED2 and the second opening OPE2 to cover the second light-emitting element ED2 and the second opening OPE2 and the sidewalls defining the second opening OPE2, and may also cover the second organic pattern ELP2, the second electrode pattern CEP2, and another one of the capping patterns CLP. The second inorganic layer TL2 may not overlap the first and third openings OPEL and OPE3, and may be disposed only in the second opening OPE2 and on part of the bank structure BNS around the second opening OPE2.

The third inorganic layer TL3 may be disposed on the third light-emitting element ED3 and the third electrode pattern CEP3. The third inorganic layer TL3 may be disposed along the third light-emitting element ED3 and the third opening OPE3 to cover the third light-emitting element ED3 and the third opening OPE3 and the sidewalls defining the third opening OPE3, and may also cover the third organic pattern ELP3, the third electrode pattern CEP3, and another one of the capping patterns CLP. The third inorganic layer TL3 may not overlap the first and second openings OPE1 and OPE2, and may be disposed only in the third opening OPE3 and on part of the bank structure BNS around the third opening OPE3.

The first inorganic layer TL1 may be formed after the formation of the first cathode CE1, the second inorganic layer TL2 may be formed after the formation of the second cathode CE2, and the third inorganic layer TL3 may be formed after the formation of the third cathode CE3. Accordingly, the first, second, and third inorganic layers TL1, TL2, and TL3 may be disposed to cover the first, second, and third electrode patterns CEP1, CEP2, and CEP3, respectively, and the first, second, and third organic patterns ELP1, ELP2, and ELP3, respectively. In a plan view, the first, second, and third inorganic layers TL1, TL2, and TL3 may be larger in size than the first, second, and third openings OPE1, OPE2, and OPE3, respectively, of the bank structure BNS. The first, second, and third inorganic layers TL1, TL2, and TL3 may be disposed to be spaced apart from one another on the bank structure BNS. Thus, part of the second bank layer BN2 of the bank structure BNS may not overlap the first, second, and third inorganic layers TL1, TL2, and TL3, and part of the top surface of the second bank layer BN2 may not be covered, but exposed by the first, second, and third inorganic layers TL1, TL2, and TL3. The second bank layer BN2 may be in direct contact with the second encapsulation layer TFE2 of the thin-film encapsulation layer TFEL.

In an embodiment, the display device 10 may include a plurality of optical patterns (OLP1, OLP2, and OLP3), which are disposed in the openings (OPE1, OPE2, and OPE3) of the bank structure BNS, on the inorganic layers (TL1, TL2, and TL3) of the first encapsulation layer TFE1.

The optical patterns (OLP1, OLP2, and OLP3) may be disposed to correspond to the emission areas (EA1, EA2, and EA3). The optical patterns (OLP1, OLP2, and OLP3) may fill the openings (OPE1, OPE2, and OPE3) of the bank structure BNS, respectively, and may be disposed on the light-emitting elements (ED1, ED2, and ED3) and the first encapsulation layer TFE1. In an embodiment, for example, the optical patterns (OLP1, OLP2, and OLP3) may include first, second, and third optical patterns OLP1, OLP2, and OLP3, which are disposed to correspond to the first, second, and third emission areas EA1, EA2, and EA3. The first, second, and third optical patterns OLP1, OLP2, and OLP3 may be disposed to overlap the first, second, and third light-emitting elements ED1, ED2, and ED3, respectively, and the first, second, and third light-emitting layers EL1, EL2, and EL3, respectively.

The optical patterns (OLP1, OLP2, and OLP3) may overlap the light-emitting elements (ED1, ED2, and ED3) and may form optical interfaces with the second encapsulation layer TFE2, which is disposed on the optical patterns (OLP1, OLP2, and OLP3). The optical patterns (OLP1, OLP2, and OLP3), like the second encapsulation layer TFE2, may include an organic insulating material, but may have a different refractive index from the second encapsulation layer TFE2. Light emitted by the light-emitting elements (ED1, ED2, and ED3) may be refracted at the interfaces by the optical patterns (OLP1, OLP2, and OLP3) and the second encapsulation layer TFE2 and may thus be emitted in an upward direction from the display device 10. In an embodiment, for example, the optical patterns (OLP1, OLP2, and OLP3) may have a greater refractive index than the second encapsulation layer TFE2. The optical patterns (OLP1, OLP2, and OLP3) and the second encapsulation layer TFE2 may include at least one selected from an acrylic resin, a siloxane resin, an epoxy resin, polyimide, and polyethylene, but the refractive index of the optical patterns (OLP1, OLP2, and OLP3) may be greater than the refractive index of the second encapsulation layer TFE2. The optical patterns (OLP1, OLP2, and OLP3) may have a refractive index of about 1.6 or greater, for example, 1.64, and the second encapsulation layer TFE2 may have a refractive index less than about 1.6, for example, about 1.5 or 1.54. However, the disclosure is not limited thereto. Alternatively, the refractive index of the optical patterns (OLP1, OLP2, and OLP3) may be less than the refractive index of the second encapsulation layer TFE2.

The optical patterns (OLP1, OLP2, and OLP3) may be disposed to fill the openings (OPE1, OPE2, and OPE3) of the bank structure BNS and may fully cover light-output areas of the light-emitting elements (ED1, ED2, and ED3). As light emitted from the light-emitting elements (ED1, ED2, and ED3) is incident upon the second encapsulation layer TFE2 through the optical patterns (OLP1, OLP2, and OLP3), the emitted light may be output through the interfaces between the optical patterns (OLP1, OLP2, and OLP3) and the second encapsulation layer TFE2.

Parts of the optical patterns (OLP1, OLP2, and OLP3) may be disposed on the organic patterns (ELP1, ELP2, and ELP3) and the electrode patterns (CEP1, CEP2, and CEP3). As the first, second, and third inorganic layers TL1, TL2, and TL3) of the first encapsulation layer TFE1 respectively cover the light-emitting elements (ED1, ED2, and ED3), the organic patterns (ELP1, ELP2, and ELP3), the electrode patterns (CEP1, CEP2, and CEP3), and the capping patterns CLP, the optical patterns (OLP1, OLP2, and OLP3) may be disposed directly on the first, second, and third inorganic layers TL1, TL2, and TL3.

In an embodiment, for example, the first optical pattern OLP1 may be formed to fill the first opening OPE1, and part of the first optical pattern OLP1 may be disposed on the first inorganic layer TL1. In an embodiment, for example, the second optical pattern OLP2 may be formed to fill the second opening OPE2, and part of the second optical pattern OLP2 may be disposed on the second inorganic layer TL2. In an embodiment, for example, the third optical pattern OLP3 may be formed to fill the third opening OPE3, and part of the third optical pattern OLP3 may be disposed on the third inorganic layer TL3. The optical patterns (OLP1, OLP2, and OLP3) may be formed in spaces formed by the bank structure BNS. The organic patterns (ELP1, ELP2, and ELP3), the electrode patterns (CEP1, CEP2, and CEP3), the capping patterns CLP, and the inorganic layers (TL1, TL2, and TL3) may be covered by different optical patterns (OLP1, OLP2, and OLP3), around different emission areas (EA1, EA2, and EA3). The first optical pattern OLP1 may cover the first organic pattern ELP1, the first electrode pattern CEP1, one of the capping patterns CLP, and the first inorganic layer TL1. The second optical pattern OLP2 may cover the second organic pattern ELP2, the second electrode pattern CEP2, another one of the capping patterns CLP, and the second inorganic layer TL2. The third optical pattern OLP3 may cover the third organic pattern ELP3, the third electrode pattern CEP3, another one of the capping patterns CLP, and the third inorganic layer TL3.

In an embodiment, as will be described later, the organic patterns (ELP1, ELP2, and ELP3), the electrode patterns (CEP1, CEP2, and CEP3), the capping patterns CLP, and the inorganic layers (TL1, TL2, and TL3) may be formed via patterning to conform to the shape of the optical patterns (OLP1, OLP2, and OLP3), and may thus be fully covered by the optical patterns (OLP1, OLP2, and OLP3). The ends of each of the organic patterns (ELP1, ELP2, and ELP3), the electrode patterns (CEP1, CEP2, and CEP3), the capping patterns CLP, and the inorganic layers (TL1, TL2, and TL3) may be aligned with the ends of the optical patterns (OLP1, OLP2, and OLP3). The distances between the organic patterns (ELP1, ELP2, and ELP3), the electrode patterns (CEP1, CEP2, and CEP3), the capping patterns CLP, and the inorganic layers (TL1, TL2, and TL3), around the emission areas (EA1, EA2, and EA3), may be the same as the minimum distance between the optical patterns (OLP1, OLP2, and OLP3).

The optical patterns (OLP1, OLP2, and OLP3) may have a different refractive index from the second encapsulation layer TFE2, and the outer surfaces of the optical patterns (OLP1, OLP2, and OLP3) may have such a shape that light may be refracted at the interfaces between the optical patterns (OLP1, OLP2, and OLP3) and the second encapsulation layer TFE2 and may be emitted in the upward direction or the thickness direction. The optical patterns (OLP1, OLP2, and OLP3) may have a greater refractive index than the second encapsulation layer TFE2, and the outer surfaces of the optical patterns (OLP1, OLP2, and OLP3) may be curved. In an embodiment, for example, the top surfaces of the optical patterns (OLP1, OLP2, and OLP3) may have a curved lens shape, and the sides of each of the optical patterns (OLP1, OLP2, and OLP3) may have an upwardly tapered shape on the inorganic layers (TL1, TL2, and TL3). In an embodiment, for example, the sides of each of the optical patterns (OLP1, OLP2, and OLP3) and the top surfaces of the inorganic layers (TL1, TL2, and TL3) may form an acute angle therebetween. Light emitted by the light-emitting elements (ED1, ED2, and ED3) may be emitted to the top surfaces of the optical patterns (OLP1, OLP2, and OLP3) and may be output by being refracted at the interfaces between the optical patterns (OLP1, OLP2, and OLP3) and the second encapsulation layer TFE2. Also, light emitted by the light-emitting elements (ED1, ED2, and ED3) to travel toward the sides of each of the optical patterns (OLP1, OLP2, and OLP3) may be refracted in the upward direction. As the display device 10 includes the optical patterns (OLP1, OLP2, and OLP3), which are disposed in the openings (OPE1, OPE2, and OPE3) of the bank structure BNS, the emission efficiency of the display device 10 can be improved.

The touch sensing layer TSU may be disposed on the thin-film encapsulation layer TFEL. The touch sensing layer TSU may include a first touch insulating layer SIL1, a second touch insulating layer SIL2, touch electrodes TEL, and a third touch insulating layer SIL3.

The first touch insulating layer SIL1 may be disposed on the thin-film encapsulation layer TFEL. The first touch insulating layer SIL1 may have insulating and optical functions. The first touch insulating layer SIL1 may include at least one inorganic layer. Alternatively, the first touch insulating layer SIL1 may be omitted.

The second touch insulating layer SIL2 may cover the first touch insulating layer SIL1. Although not specifically illustrated, other touch electrodes TEL may be disposed on the first touch insulating layer SIL1 and may be covered by the second touch insulating layer SIL2. The second touch insulating layer SIL2 may have insulating and optical functions. In an embodiment, for example, the second touch insulating layer SIL2 may be an inorganic film including at least one selected from a silicon nitride layer, a silicon oxy nitride layer, a silicon oxide layer, a titanium oxide layer, and an aluminum oxide layer.

Some of the touch electrodes TEL may be disposed on the second touch insulating layer SIL2. The touch electrodes TEL may not overlap the first, second, and third emission areas EA1, EA2, and EA3. The touch electrodes TEL may be formed as single layers, each layer including Mo, Ti, Cu, Al, ITO, or an Ag—Pd—Cu (APC) alloy or as stacks of Al and Ti (e.g., Ti/Al/Ti), Al and ITO (e.g., ITO/AI/ITO), and an APC alloy and ITO (e.g., ITO/APC/ITO).

The third touch insulating layer SIL3 may cover the touch electrodes TEL and the second touch insulating layer SIL2. The third touch insulating layer SIL3 may have insulating and optical functions. The third touch insulating layer SIL3 may include or be formed of at least one selected from the aforementioned materials for forming the second touch insulating layer SIL2.

The light-blocking layer BM may be disposed on the touch sensing layer TSU. The light-blocking layer BM may include the opening holes (OPT1, OPT2, and OPT3), which are disposed to overlap the emission areas (EA1, EA2, and EA3). In an embodiment, for example, a first opening hole OPT1 may be disposed to overlap the first emission area EA1, a second opening hole OPT2 may be disposed to overlap the second emission area EA2, and a third opening hole OPT3 may be disposed to overlap the third emission area EA3. The opening holes (OPT1, OPT2, and OPT3) may have a larger area or size than the emission areas (EA1, EA2, and EA3), which are defined by the bank structure BNS. As the opening holes (OPT1, OPT2, and OPT3) of the light-blocking layer BM are formed to be larger in size than the emission areas (EA1, EA2, and EA3), light emitted from the emission areas (EA1, EA2, and EA3) can be visible to the user not only at the front, but also at the sides of the display device 10.

The light-blocking layer BM may include a light-absorbing material. In an embodiment, for example, the light-blocking layer BM may include an inorganic black pigment or an organic black pigment. The inorganic black pigment may be, but is not limited to, carbon black, and the organic black pigment may include, but is not limited to, at least one selected from lactam black, perylene black, and aniline black. The light-blocking layer BM can prevent visible light from infiltrating between the first, second, and third emission areas EA1, EA2, and EA3 to cause color mixing and can thus improve the color reproducibility of the display device 10.

The display device 10 may include the color filters (CF1, CF2, and CF3), which are disposed in the emission areas (EA1, EA2, and EA3), respectively. The color filters (CF1, CF2, and CF3) may be disposed to correspond to the emission areas (EA1, EA2, and EA3). In an embodiment, for example, the color filters (CF1, CF2, and CF3) may be disposed on the light-blocking layer BM, which includes the opening holes (OPT1, OPT2, and OPT3) that are disposed to correspond to the emission areas (EA1, EA2, and EA3). The opening holes (OPT1, OPT2, and OPT3) may be defined or formed to overlap the emission areas (EA1, EA2, and EA3) and the openings (OPE1, OPE2, and OPE3) of the bank structure BNS and may form light-output areas that output light emitted by the emission areas (EA1, EA2, and EA3). The color filters (CF1, CF2, and CF3) may have a larger area than the opening holes (OPT1, OPT2, and OPT3) of the light-blocking layer BM and may completely cover the light-output areas formed by the opening holes (OPT1, OPT2, and OPT3).

The color filters (CF1, CF2, and CF3) may include first, second, and third color filters CF1, CF2, and CF3. The color filters (CF1, CF2, and CF3) may include a colorant such as a pigment or dye capable of absorbing all wavelengths of light except for a particular wavelength range and may be disposed to correspond to the colors of light emitted from the emission areas (EA1, EA2, and EA3). In an embodiment, for example, the first color filter CF1 may be disposed to overlap the first emission area EA1 and may be a red color filter capable of transmitting only red light therethrough, the second color filter CF2 may be disposed to overlap the second emission area EA2 and may be a green color filter capable of transmitting only green light therethrough, and the third color filter CF3 may be disposed to overlap the third emission area EA3 and may be a blue color filter capable of transmitting only blue light therethrough.

The color filters (CF1, CF2, and CF3) may be spaced apart from one another on the light-blocking layer BM. The color filters (CF1, CF2, and CF3) may have a larger area than the opening holes (OPT1, OPT2, and OPT3) of the light-blocking layer BM to cover the opening holes (OPT1, OPT2, and OPT3) of the light-blocking layer BM and to be spaced apart from one another on the light-blocking layer BM, but the disclosure is not limited thereto. Alternatively, the color filters (CF1, CF2, and CF3) may partially overlap one another. Different color filters (CF1, CF2, and CF3) may overlap with one another on the light-blocking layer BM, which corresponds to an area not overlapping the emission areas (EA1, EA2, and EA3). In such an embodiment, as the color filters (CF1, CF2, and CF3) are disposed to overlap one another, the intensity of reflected light of external light can be reduced. Also, the color of reflected light of external light can be controlled by controlling the layout, the shape, and size of the color filters (CF1, CF2, and CF3).

The color filters (CF1, CF2, and CF3) of the color filter layer CFL may be disposed on the light-blocking layer BM. The color filters (CF1, CF2, and CF3) may be disposed to correspond to the emission areas (EA1, EA2, and EA3), the openings (OPE1, OPE2, and OPE3), and the opening holes (OPT1, OPT2, and OPT3). In an embodiment, for example, the first color filter CF1 may be disposed to correspond to the first emission area EA1, the second color filter CF2 may be disposed to correspond to the second emission area EA2, and the third color filter CF3 may be disposed to correspond to the third emission area EA3. The first color filter CF1 may be disposed in the first opening hole OPT1 of the light-blocking layer BM, the second color filter CF2 may be disposed in the second opening hole OPT2 of the light-blocking layer BM, and the third color filter CF3 may be disposed in the third opening hole OPT3 of the light-blocking layer BM. The color filters (CF1, CF2, and CF3) may have a larger area than the opening holes (OPT1, OPT2, and OPT3) of the light-blocking layer BM, and parts of the color filters (CF1, CF2, and CF3) may be disposed directly on the light-blocking layer BM.

An overcoat layer OC may be disposed on the color filters (CF1, CF2, and CF3) may be disposed on the color filters (CF1, CF2, and CF3) and may planarize the tops of the color filters (CF1, CF2, and CF3). The overcoat layer OC may be a colorless light-transmitting layer not having a color in a visible wavelength range. In an embodiment, for example, the overcoat layer OC may include a colorless light-transmitting organic material such as an acrylic resin.

The light-emitting elements (ED1, ED2, and ED3), which are disposed in the display area DA, may be disposed in the emission areas (EA1, EA2, and EA3), which are formed by the bank structure BNS. The cathodes (CE1, CE2, and CE3) of the light-emitting elements (ED1, ED2, and ED3) may be electrically connected to one another via the first bank layer BN1 of the bank structure BNS. The cathodes (CE1, CE2, and CE3) of the light-emitting elements (ED1, ED2, and ED3) and the first bank layer BN1 may form (or collectively define) cathodes (common electrodes?) in the display area DA.

The fabrication of the display device 10 will hereinafter be described.

FIGS. 8 through 16 are cross-sectional views illustrating a display area of a display device for explaining a method of fabricating a display device according to an embodiment of the disclosure.

FIGS. 8 through 16 illustrate how to form a bank structure BNS and light-emitting elements (ED1, ED2, and ED3) of a light-emitting element layer EML. A detailed description of how to form each of the layers of the display device 10 will be omitted, and instead, the order in which the layers of the display device 10 are formed will hereinafter be described.

Referring to FIG. 8, a plurality of anodes (AE1, AE2, and AE3), a sacrificial layer SFL, an inorganic insulating layer ISL, and first and second bank material layers BNL1 and BNL2 are formed.

Although not specifically illustrated, a TFT layer TFTL may be disposed on a substrate SUB. The structure of the TFT layer TFTL is substantially the same as that described above with reference to FIG. 6, and thus, any repetitive detailed description thereof will be omitted.

The anodes (AE1, AE2, and AE3) may be spaced apart from one another on the TFT layer TFTL. The anodes (AE1, AE2, and AE3) may include first, second, and third anodes AE1, AE2, and AE3, which are of first, second, and third light-emitting elements ED1, ED2, and ED3, respectively. The first, second, and third anodes AE1, AE2, and AE3 may be spaced apart from one another on the TFT layer TFTL.

The sacrificial layer SFL may be disposed on the anodes (AE1, AE2, and AE3). The sacrificial layer SFL may be initially disposed on the anodes (AE1, AE2, and AE3) and may then be removed to provide spaces in which to arrange light-emitting layers (EL1, EL2, and EL3). The sacrificial layer SFL may allow the inorganic insulating layer ISL not to be in contact with the top surfaces of the anodes (AE1, AE2, and AE3). The sacrificial layer SFL may include an oxide semiconductor. In an embodiment, for example, the sacrificial layer SFL may include at least one of indium gallium zinc oxide (IGZO), zinc tin oxide (ZTO), and indium tin oxide (ITO).

The inorganic insulating layer ISL and the first and second bank material layers BNL1 and BNL2 may be disposed on the sacrificial layer SFL. The inorganic insulating layer ISL may be disposed to cover all the sacrificial layer SFL and the entire TFT layer TFTL, and the first and second bank material layers BNL1 and BNL2 may be disposed to cover the entire inorganic insulating layer ISL. The first and second bank material layers BNL1 and BNL2 may be sequentially stacked. The first bank material layer BNL1 may be disposed directly on the inorganic insulating layer ISL, and the second bank material layer BNL2 may be disposed on the first bank material layer BNL1. The first and second bank material layers BNL1 and BNL2 may be partially etched in a subsequent process, thereby forming the first and second bank layers BN1 and BN2 of the bank structure BNS of FIG. 6. The first and second bank material layers BNL1 and BNL2 may include different metal materials, respectively, and may form the first and second bank layers BN1 and BN2, respectively.

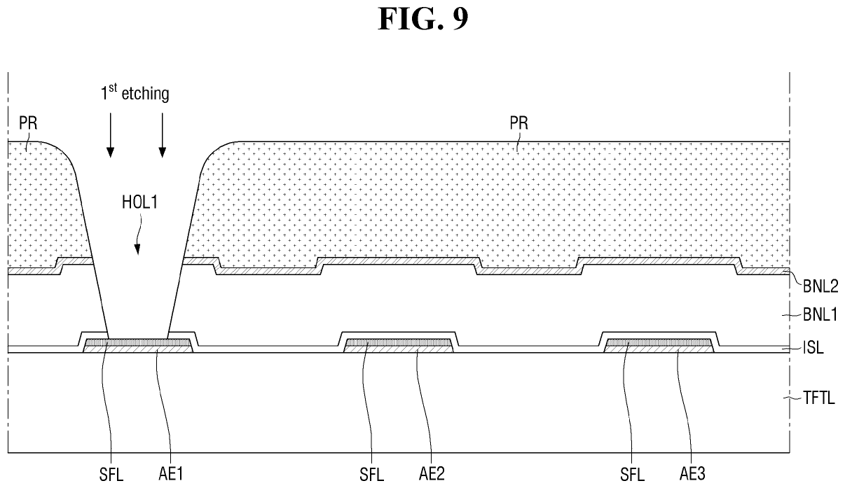

Thereafter, referring to FIG. 9, photoresist PR is formed on the first and second bank material layers BNL1 and BNL2, and a first etching process (1st etching), which etches parts of the first and second bank material layers BNL1 and BNL2, is performed using the photoresist PR as a mask, thereby forming a first hole HOL1.

The photoresist PR may be disposed on the first and second bank material layers BNL1 and BNL2 and may include parts that are spaced apart from each other. The photoresist PR may not overlap the first anode AE1, on the second bank material layer BNL2, and may expose parts of the first and second bank material layers BNL1 and BNL2 that overlap the first anode AE1.

Dry etching may be performed as the first etching process (1st etching). As dry etching is performed as the first etching process (1st etching), the first and second bank material layers BNL1 and BNL2, which include different materials from each other, may be anisotropically etched. As the first and second bank material layers BNL1 and BNL2 and the inorganic insulating layer ISL are partially etched together, the sacrificial layer SFL may be partially exposed. The first hole HOL1 may be formed in an area overlapping with the first anode AE1 and may form a first opening OPE1 of the bank structure BNS.

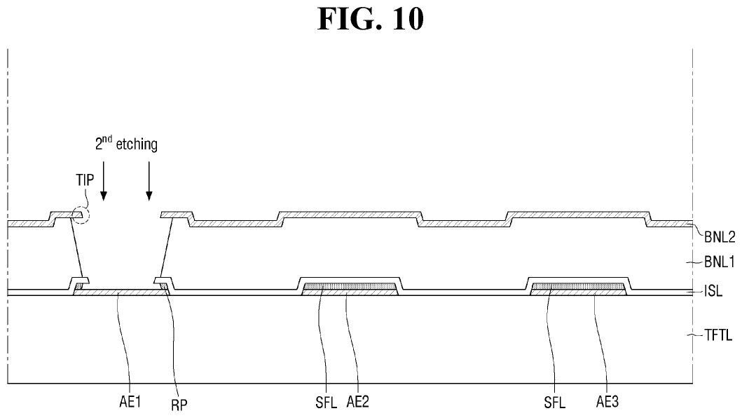

Thereafter, referring to FIG. 10, a second etching process (2^{nd} etching), which removes part of the sacrificial layer SFL on the first anode AE1, is performed. The sacrificial layer SFL may include an oxide semiconductor layer, and wet etching may be performed as the second etching process (2^{nd} etching). As the sacrificial layer SFL is removed by the second etching process (2^{nd} etching), the inner sidewall defining the first hole HOL1 may be etched. The first bank material layer BNL1 may be etched faster than the second bank material layer BNL2, and tips TIP, which protrude beyond the side surfaces of the first bank material layer BNL1, may be formed in the second bank material layer BNL2. Undercuts may be formed on the side surfaces of the first bank material layer BNL1, below the tips TIP of the second bank material layer BNL2. As a result of the second etching process (2^{nd} etching), the first hole HOL1 may form the first opening OPE1 or a first emission area EA1.

The sacrificial layer SFL may be partially removed from the first hole HOL1 and from between the inorganic insulating layer ISL and the first anode AE1. The sacrificial layer SFL may not be completely removed but may remain between the inorganic insulating layer ISL and the first anode AE1 as a residual pattern RP. As the sacrificial layer SFL is removed, a gap may be formed between the first anode AE1 and the inorganic insulating layer ISL, and a first light-emitting layer EL1 may be formed later on the first anode AE1 to fill the gap.

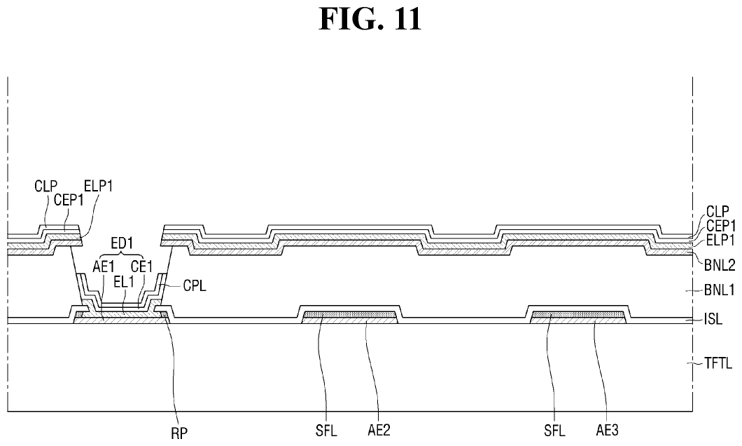

Thereafter, referring to FIG. 11, the first light-emitting layer EL1, a first cathode CE1, and a capping layer CPL are deposited on the first anode AE1, thereby forming a first light-emitting element ED1. The first light-emitting layer EL1 and the first cathode CE1 may be formed in the first opening OPE1, and the materials of the first light-emitting layer EL1 and the first cathode CE1 may also be deposited even on the second bank material layer BNL2, thereby forming a plurality of patterns. In an embodiment, for example, some of the materials of the first light-emitting layer EL1 and the first cathode CE1 may be deposited on the second bank material layer BNL2, thereby forming a first organic pattern ELP1 and a first electrode pattern CEP1. Part of the capping layer CPL may be disposed in the first opening OPE1 to cover the first light-emitting element ED1, and another part of the capping layer CPL may be disposed on the second bank material layer BNL2 to cover the first organic pattern ELP1 and the first electrode pattern CEP1. The structures of the first light-emitting layer EL1, the first cathode CE1, the first organic pattern ELP1, and the first electrode pattern CEP1 are as already described above.

The first light-emitting layer EL1 and the first cathode CE1 may be formed by deposition. The materials of the first light-emitting layer EL1 and the first cathode CE1 may not be properly deposited due to the tips TIP of the second bank material layer BNL2. However, as the materials of the first light-emitting layer EL1 and the first cathode CE1 are deposited diagonally, rather than perpendicularly, with respect to the top surface of the substrate SUB, the materials of the first light-emitting layer EL1 and the first cathode CE1 can be deposited even in regions on the first bank material layer BNL1 that are hidden by the tips TIP.

In an embodiment, for example, a deposition process for forming the first light-emitting layer EL1 may be performed in a direction not perpendicular to the top surface of the first anode AE1, for example, at a first angle with respect to the top surface of the first anode AE1. The material of light-emitting layers (EL1, EL2, and EL3) may be deposited at an angle in a range of about 45° to about 50° with respect to the top surfaces of the anodes (AE1, AE2, and AE3). The first light-emitting layer EL1 may be formed to fill the space between the first anode AE1 and the inorganic insulating layer ISL and may be formed even in regions hidden or covered by the tips TIP of the second bank material layer BNL2. In an embodiment, for example, the first light-emitting layer EL1 may be disposed on parts of the side surfaces of the first bank material layer BNL1, hidden by the tips TIP of the second bank material layer BNL2.

A deposition process for forming the first cathode CE1 may be performed in a direction not perpendicular to the top surface of the first anode AE1, for example, at a second angle with respect to the top surface of the first anode AE1. The material of cathodes (CE1, CE2, and CE3) may be deposited at an angle of 30° or less with respect to the top surfaces of the anodes (AE1, AE2, and AE3). The first cathode CE1 may be disposed on the first light-emitting layer EL1 and may be formed even in regions hidden by the tips TIP of the second bank material layer BNL2. In an embodiment, for example, the first cathode CE1 may be disposed on parts of the side surfaces of the first bank material layer BNL1, hidden or covered by the tips TIP of the second bank material layer BNL2.

Deposition processes for forming the light-emitting layers (EL1, EL2, and EL3) may be performed more horizontally than deposition processes for forming the cathodes (CE1, CE2, and CE3). As a result, the contact areas of the cathodes (CE1, CE2, and CE3) and the first bank material layer BNL1 (or the side surfaces of the first bank material layer BNL1) may be greater than the contact areas of the light-emitting layers (EL1, EL2, and EL3) and the first bank material layer BNL1 (or the side surfaces of the first bank material layer BNL1). Alternatively, the cathodes (CE1, CE2, and CE3) may be deposited to a greater height than the light-emitting layers (EL1, EL2, and EL3), on the first bank material layer BNL1 (or the side surfaces of the first bank material layer BNL1). Different cathodes (CE1, CE2, and CE3) may be in contact with the first bank material layer BNL1 or the first bank layer BN1, which has a high conductivity, and may thus be electrically connected to one another.

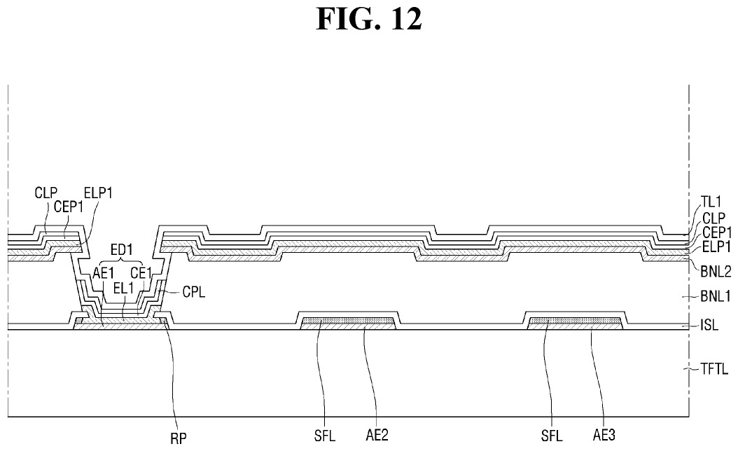

Thereafter, referring to FIG. 12, a first inorganic layer TL1, which covers the first light-emitting element ED1 and the capping layer CPL, is formed. The first inorganic layer TL1, unlike the light-emitting layers (EL1, EL2, and EL3) and the cathodes (CE1, CE2, and CE3), may be formed by CVD and may have a uniform thickness regardless of the underlying step differences. The first inorganic layer TL1 may be formed to completely cover the first light-emitting element ED1, the first and second bank material layers BNL1 and BNL2, and the capping layer CPL. The first inorganic layer TL1 may be deposited even below the tips TIP of the second bank material layer BNL2.

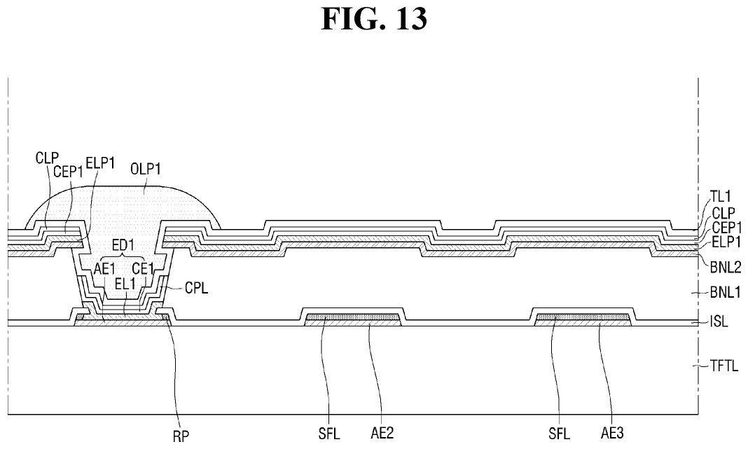

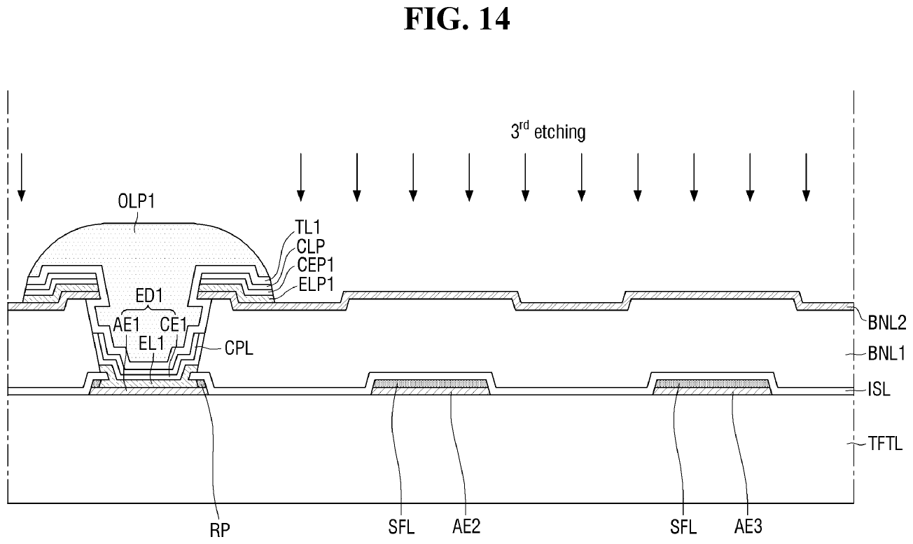

Thereafter, referring to FIGS. 13 and 14, a first optical pattern OLP1 is formed on the first inorganic layer TL1, and a third etching process (3^{rd} etching), which removes parts of the first organic pattern ELP1, the first electrode pattern CEP1, the capping layer CPL, and the first inorganic layer TL1 on the first and second bank material layers BNL1 and BNL2, is performed.

The first optical pattern OLP1 may be disposed in the first opening OPEL to overlap the first light-emitting element ED1. The entire first organic pattern ELP1, the entire first electrode pattern CEP1, an entire capping pattern CLP, and the entire first inorganic layer TL1 except for parts thereof around the first opening OPE1 or the first light-emitting element ED1 may be removed. The entire second bank material layer BNL2 except for part thereof around the first opening OPE1 or the first light-emitting element ED1 may be exposed. Dry etching using a fluorine (F)-based etchant may be performed as the third etching process (3^{rd} etching), which removes part of the first inorganic layer TL1 on the first and second bank material layers BNL1 and BNL2. The first optical pattern OLP1 may function as a mask for etching the first organic pattern ELP1, the first electrode pattern CEP1, the capping pattern CLP, and the first inorganic layer TL1, and the ends of each of the etched first organic pattern ELP1, the etched first electrode pattern CEP1, the etched capping pattern CLP, and the etched first inorganic layer TL1 may be aligned with the ends of the first optical pattern OLP1.

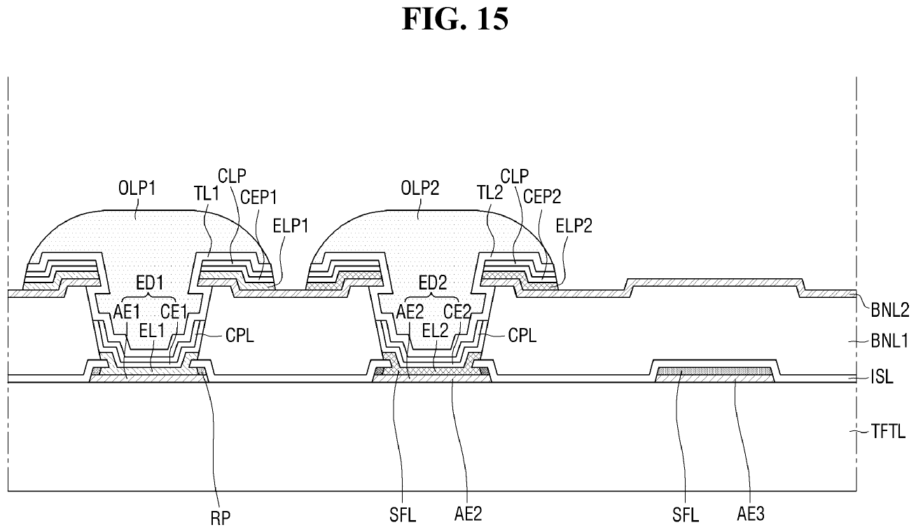

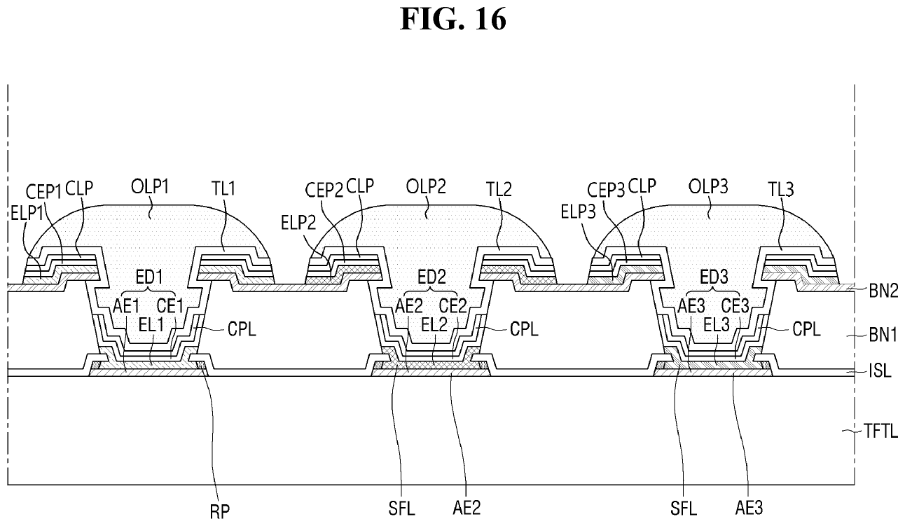

In this manner, a first light-emitting element ED1 and a first inorganic layer TL1 covering the first light-emitting element ED1, the first organic pattern ELP1, the first electrode pattern CEP1, and the capping layer CPL may be obtained. Referring to FIGS. 15 and 16, a second light-emitting element ED2, a third light-emitting element ED3, a second organic pattern ELP2, a third organic pattern ELP3, a second electrode pattern CEP2, a third electrode pattern CEP3, a second inorganic layer TL2, a third inorganic layer TL3, a second optical pattern OLP2, and a third optical pattern OLP3 may be formed by repeatedly performing processes similar to the processes for forming the first light-emitting element ED1 and the first inorganic layer TL1.

Thereafter, although not specifically illustrated, second and third encapsulation layers TFE2 and TFE2 are formed on a first encapsulation layer TFE1 and the bank structure BNS, and a touch sensing layer TSU, a light-blocking layer BM, a color filter layer CFL, and an overcoat layer OC are formed, thereby obtaining the display device 10.

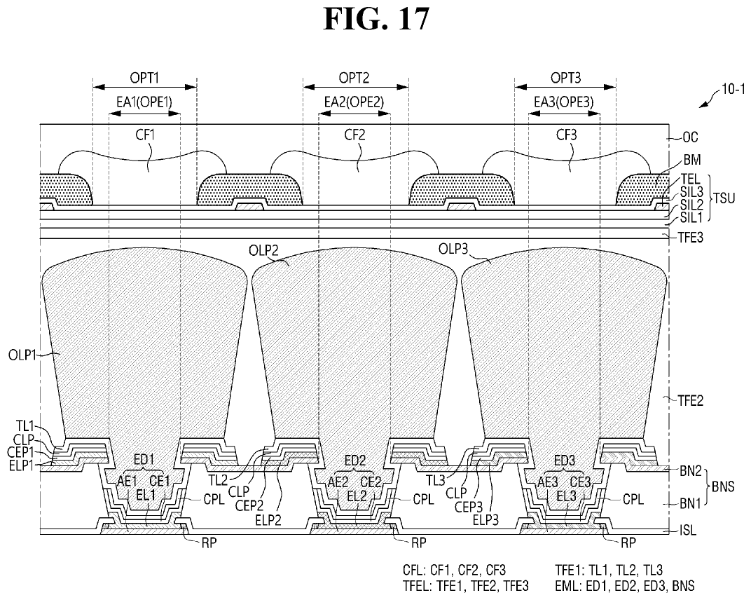

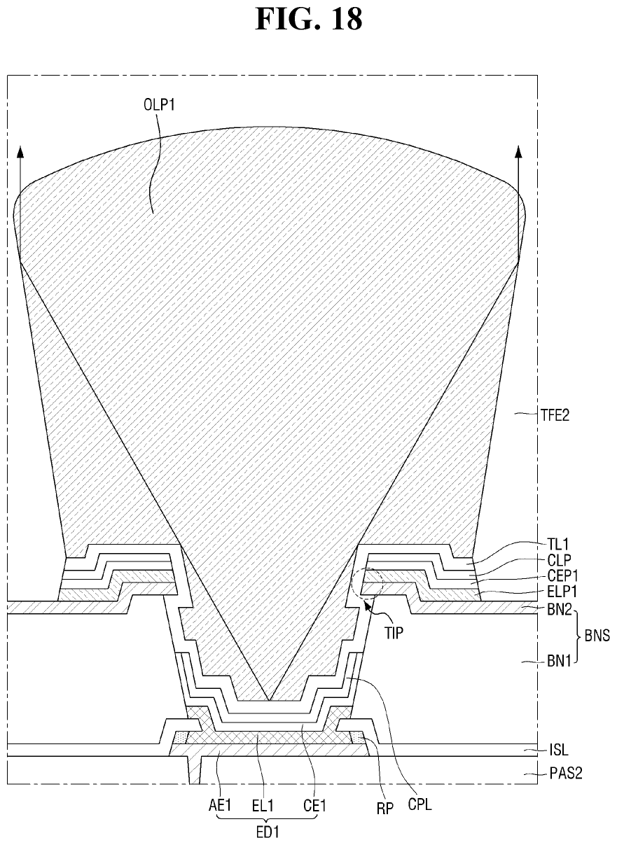

FIG. 17 is a cross-sectional view illustrating part of a display device according to an alternative embodiment of the disclosure. FIG. 18 is an enlarged cross-sectional view illustrating a first emission area of FIG. 17.

Referring to FIGS. 17 and 18, an alternative embodiment of a display device 10 may be substantially the same as the embodiments of the display device 10 described above except for the relationship between the refractive index of optical patterns (OLP1, OLP2, and OLP3) and a second encapsulation layer TFE2 of a thin-film encapsulation layer TFEL. In an embodiment, for example, the optical patterns (OLP1, OLP2, and OLP3) may have a less refractive index than the second encapsulation layer TFE2. The optical patterns (OLP1, OLP2, and OLP3) may have a refractive index less than about 1.6, for example, about 1.5 or 1.54, and the second encapsulation layer TFE2 may have a refractive index of about 1.6 or greater, for example, 1.64. The relationship between the refractive index of the optical patterns (OLP1, OLP2, and OLP3) and the second encapsulation layer TFE2 may vary as long as the refractive index of the optical patterns (OLP1, OLP2, and OLP3) and the second encapsulation layer TFE2 have different refractive indexes and can form optical interfaces therebetween while being in contact with one another.

The top surfaces of the optical patterns (OLP1, OLP2, and OLp3) may have a curved lens shape, and the sides of each of the optical patterns (OLP1, OLP2, and OLP3) may have a downwardly tapered shape on inorganic layers (TL1, TL2, and TL3). In an embodiment, for example, the sides of each of the optical patterns (OLP1, OLP2, and OLP3) and the top surfaces of the inorganic layers (TL1, TL2, and TL3) may form an obtuse angle therebetween. As in the embodiment of FIGS. 17 and 18, unlike in the embodiment of FIGS. 6 and 7, the optical patterns (OLP1, OLP2, and OLP3) have a less refractive index than the second encapsulation layer TFE2, the shape of the optical patterns (OLP1, OLP2, and OLP3) may be varied such that light incident upon the sides of each of the optical patterns (OLP1, OLP2, and OLP3) may be emitted in an upward direction. Also, as the sides of each of the optical patterns (OLP1, OLP2, and OLP3) are downwardly tapered, the minimum distance between the optical patterns (OLP1, OLP2, and OLP3) may be less than the distance between the inorganic layers (TL1, TL2, and TL3).

The optical patterns (OLP1, OLP2, and OLP3) may have a different refractive index from the second encapsulation layer TFE2, and the outer surfaces of the optical patterns (OLP1, OLP2, and OLP3) may have such a shape that light may be refracted at the interfaces between the optical patterns (OLP1, OLP2, and OLP3) and the second encapsulation layer TFE2 and may be emitted in the upward direction. In an embodiment, for example, the optical patterns (OLP1, OLP2, and OLP3) may have a less refractive index than the second encapsulation layer TFE2, and the sides of each of the optical patterns (OLP1, OLP2, and OLP3) may be downwardly tapered. Light incident upon the sides of each of the optical patterns (OLP1, OLP2, and OLP3), among beams of light emitted by light-emitting elements (ED1, ED2, and ED3), may be refracted in the upward direction by the sides of each of the optical patterns (OLP1, OLP2, and OLP3). In such an embodiment, as the display device 10_1 includes the optical patterns (OLP1, OLP2, and OLP3), which are disposed in openings (OPE1, OPE2, and OPE3) of a bank structure BNS, the emission efficiency of the display device 10_1 can be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
first and second anodes disposed on a substrate to be spaced apart from each other;
an inorganic insulating layer disposed on the substrate and in part on the first and second anodes;
a bank structure disposed on the inorganic insulating layer, wherein a first opening and a second opening, which overlap the first and second anodes, respectively, are defined through the bank structure;
a first light-emitting layer disposed on the first anode;
a second light-emitting layer disposed on the second anode;
a first cathode disposed on the first light-emitting layer;
a second cathode disposed on the second light-emitting layer;
a first encapsulation layer including a first inorganic layer, which is disposed on the first cathode, and a second inorganic layer, which is disposed on the second cathode;
a first optical pattern disposed on the first inorganic layer and in part in the first opening, wherein the first optical pattern overlaps the first light-emitting layer;
a second optical pattern disposed on the second inorganic layer and in the second opening, wherein the second optical pattern overlaps the second light-emitting layer;
a second encapsulation layer disposed on the first encapsulation layer, the first optical pattern, and the second optical pattern;
a third encapsulation layer disposed on the second encapsulation layer,
wherein
the bank structure includes a first bank layer and a second bank layer, wherein the second bank layer is disposed on the first bank layer, includes a different material from the first bank layer, and includes a tip protruding further than the first bank layer from each of sidewalls of the bank structure defining the first and second openings, and
the first and second optical patterns have a different refractive index from the second encapsulation layer.

2. The display device of claim 1, wherein
the first bank layer includes aluminum (Al), and
the second bank layer includes titanium (Ti).

3. The display device of claim 1, wherein the first and second cathodes are in direct contact with side surfaces of the first bank layer.

4. The display device of claim 1, further comprising:
a first organic pattern disposed on the second bank layer to surround the first opening, wherein the first organic pattern includes a same material as the first light-emitting layer;
a first electrode pattern disposed on the first organic pattern, wherein the first electrode pattern includes a same material as the first cathode;
a second organic pattern disposed on the second bank layer to surround the second opening, wherein the second organic pattern includes a same material as the second light-emitting layer; and
a second electrode pattern disposed on the second organic pattern, wherein the second electrode pattern includes a same material as the second cathode,
wherein
the first inorganic layer is disposed on the first electrode pattern, and
the second inorganic layer is disposed on the second electrode pattern.

5. The display device of claim 4, wherein
the first inorganic layer is disposed on the sidewalls of the bank structure defining the first opening, and
the second inorganic layer is disposed on the sidewalls of the bank structure defining the second opening.

6. The display device of claim 1, wherein
outer surfaces of the first and second optical patterns have a curved shape,
ends of an outer surface of the first optical pattern are aligned with the first inorganic layer, and
ends of an outer surface of the second optical pattern are aligned with the second inorganic layer.

7. The display device of claim 6, wherein
the first and second optical patterns have a greater refractive index than the second encapsulation layer, and
the ends of the outer surface of each of the first and second optical patterns form an acute angle with a top surface of the first or second inorganic layer.

8. The display device of claim 7, wherein
the first and second optical patterns have a refractive index of about 1.6 or greater, and
the second encapsulation layer has a refractive index less than about 1.6.

9. The display device of claim 7, wherein a minimum distance between the first and second optical patterns is the same as a distance between the first and second inorganic layers.

10. The display device of claim 6, wherein
the first and second optical patterns have a less refractive index than the second encapsulation layer, and
the ends of the outer surface of each of the first and second optical patterns form an obtuse angle with a top surface of the first or second inorganic layer.

11. The display device of claim 10, wherein
the first and second optical patterns have a refractive index less than about 1.6, and
the second encapsulation layer has a refractive index of about 1.6 or greater.

12. The display device of claim 10, wherein a minimum distance between the first and second optical patterns is less than a distance between the first and second inorganic layers.

13. The display device of claim 1, wherein
the inorganic insulating layer is not in contact with top surfaces of the first and second anodes,
the first light-emitting layer is disposed in part between the first anode and the inorganic insulating layer, and
the second light-emitting layer is disposed in part between the second anode and the inorganic insulating layer.

14. The display device of claim 13, further comprising:
residual patterns disposed between the inorganic insulating layer and the first and second anodes.

15. The display device of claim 1, further comprising:
a touch layer disposed on the third encapsulation layer;
a light-blocking layer provided with a first opening hole, which overlaps the first opening, and a second opening hole, which overlaps the second opening; and
first and second color filters disposed on the light-blocking layer, wherein the first and second color filters overlap the first and second opening holes, respectively.

16. A method of fabricating a display device, the method comprising:
forming a plurality of anodes, which are spaced apart from one another on a substrate, a sacrificial layer, which is disposed on the anodes, and first and second bank material layers, which are disposed on the sacrificial layer, on the substrate;
forming a first hole, which overlaps one of the anodes and exposes part of the sacrificial layer on a corresponding anode, through the first and second bank material layers;
forming a tip, which is a part of the second bank material layer protruding beyond side surfaces of the first bank material layer, by etching the sacrificial layer and sidewalls defining the first hole;
forming a first light-emitting layer and a first cathode on the anode in a first opening, which is formed by etching the first hole, and forming a first inorganic layer on the first cathode and the second bank material layer;
forming a first optical pattern on the first inorganic layer, in the first opening;
etching the first inorganic layer in a way such that the first inorganic layer on the second bank material layer, except for a part thereof overlapping the first optical pattern, is removed; and
forming an organic encapsulation layer on the first optical pattern, wherein the organic encapsulation layer has a different refractive index from the first optical pattern.

17. The method of claim 16, further comprising, after the etching the first inorganic layer and before the forming the organic encapsulation layer:
forming a second hole through the first and second bank material layers to overlap a corresponding one of the anodes;
forming a second opening by etching sidewalls defining the second hole;
forming a second light-emitting layer and a second cathode on the corresponding one of the anodes in the second opening;
forming a second inorganic layer on the second cathode and the second bank material layer;
forming a second optical pattern on the second inorganic layer, in the second opening; and
etching the second inorganic layer in a way such that the second inorganic layer on the second bank material layer, except for a part thereof overlapping the second optical pattern, is removed.

18. The method of claim 17, wherein
the first and second optical patterns have a greater refractive index than the organic encapsulation layer,
outer surfaces of the first and second optical patterns have a curved shape, and
ends of an outer surface of each of the first and second optical patterns form an acute angle with a top surface of the first or second inorganic layer.

19. The method of claim 17, wherein
the ends of the outer surface of the first optical pattern are aligned with the first inorganic layer, and
the ends of the outer surface of the second optical pattern are aligned with the second inorganic layer.

20. The method of claim 16, wherein
the first bank material layer includes aluminum (Al), and
the second bank material layer includes titanium (Ti).
